(19) United States
(12) Patent Application Publication
(10) Pub. No.: US 2026/0101589 A1
(43) Pub. Date: Apr. 9, 2026

(54) SEMICONDUCTOR DEVICE AND METHOD OF GENERATING LAYOUT PLAN FOR SEMICONDUCTOR DEVICE

(71) Applicant: Taiwan Semiconductor Manufacturing Company, Ltd., Hsinchu (TW)

(72) Inventors: Kuan Yu CHEN, Hsinchu (TW); Hui-Zhong ZHUANG, Hsinchu (TW); Chun-Yen LIN, Hsinchu (TW); Hung-Li CHIANG, Hsinchu (TW); Wei-Cheng LIN, Hsinchu (TW); Jiann-Tyng TZENG, Hsinchu (TW)

(73) Assignee: Taiwan Semiconductor Manufacturing Company, Ltd., Hsinchu (TW)

(21) Appl. No.: 19/008,088

(22) Filed: Jan. 2, 2025

Related U.S. Application Data
(60) Provisional application No. 63/703,782, filed on Oct. 4, 2024.

(51) Int. Cl. H10D 89/10; G06F 30/392; H01L 23/522; H01L 23/528

(52) U.S. Cl. CPC H10D 89/10; G06F 30/392; H10W 20/42; H10W 20/427

(57) ABSTRACT

An embodiment semiconductor device includes a first circuit cell and a second circuit cell abutting the first circuit cell at a cell boundary therebetween. The first circuit cell includes first one or more conductive lines in a first metallization line region of a first metallization layer and includes first one or more via structures under the first metallization layer. The second circuit cell includes second one or more conductive lines in a second metallization line region of the first metallization layer and includes second one or more via structures under the first metallization layer. The first metallization line region and the second metallization line region are spaced apart by a shared space extending along the cell boundary. The first one or more via structures and the second one or more via structures are within an area having a zig-zag pattern along the cell boundary.

### PRIORITY CLAIM AND CROSS-REFERENCE

This patent application claims the benefit of U.S. Provisional Patent Application No.: 63/703,782 filed on Oct. 4, 2024, the entire disclosure of which is hereby incorporated by reference.

### BACKGROUND

An integrated circuit (IC) includes one or more semiconductor devices. While designing a semiconductor device, designers may indicate the sizes and shapes of various features of the semiconductor device in the form of layout patterns in a layout plan for the semiconductor device. The components and structures of the semiconductor structure are usually formed based on forming and/or removing features of various layers of semiconductor materials or structures indicated by the layout patterns in the layout plan. In some applications, a semiconductor device includes a collection of modules which carry out higher-level functions in accordance with the semiconductor device's design specifications. The modules are often built from a combination of circuit cells, each of which represents one or more semiconductor structures configured to perform a specific function. In some applications, a layout plan includes layout cells corresponding to various circuit cells and having pre-designed layout patterns, and the layout cells are sometimes known as standard cells. In many applications, templates of the standard cells are stored in the standard cell libraries (hereinafter “libraries” or “cell libraries” for simplicity) and accessible by various tools, such as electronic design automation (EDA) tools, usable to generate, optimize, and verify designs for semiconductor devices.

As the semiconductor devices have become smaller and more complex, some features of the same layer of semiconductor material or structure, as limited by the design rules of the corresponding manufacturing process, may be too close to be manufactured simultaneously. Instead, manufacturing features that are too close to one another as limited by the design rules may be manufactured based on multiple patterning using multiple masks, which comes with an increased cost in making additional masks, an increased cost in executing additional lithography, deposition, and/or removal processes, increased complexity in aligning different masks of the same layer, and/or a decreased yield rate in manufacturing the semiconductor device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a semiconductor device, in accordance with some embodiments.

FIG. 2 is a cross-sectional view of a semiconductor device, in accordance with some embodiments.

FIGS. 3A-3E are layout diagrams of various layout cell examples, in accordance with some embodiments.

FIGS. 4A-4B are layout diagrams of different portions of a first layout plan example, in accordance with some embodiments.

FIGS. 5A-5B are layout diagrams of different portions of a second layout plan example, in accordance with some embodiments.

FIG. 6 is a diagram of a plurality of placement sites of a layout plan for a semiconductor device, in accordance with some embodiments.

FIG. 7A is a layout diagram of a portion of a base layout cell example, in accordance with some embodiments.

FIGS. 7B-7I are layout diagrams of various portions of different layout cell examples based on the base layout cell of FIG. 7A, in accordance with some embodiments.

FIGS. 8A-8C are simplified layout diagrams of various flipped variations of a base candidate layout cell, in accordance with some embodiments.

FIGS. 9A-9B are simplified layout diagrams of layout plan examples, in accordance with some embodiments.

FIG. 10A is a circuit diagram of an AND-OR-INVERT (AOI) logic, in accordance with some embodiments.

FIGS. 10B-10D are layout diagrams of candidate layout cells of the AOI logic in FIG. 10A, in accordance with some embodiments.

FIG. 11A is a circuit diagram of a NAND logic, in accordance with some embodiments.

FIGS. 11B-11C are layout diagrams of candidate layout cells of the NAND logic in FIG. 11A, in accordance with some embodiments.

FIGS. 12A-12B are diagrams of simplified layout plan examples, in accordance with some embodiments.

FIG. 13 is a flowchart of a method of generating a layout plan for a semiconductor device, in accordance with some embodiments.

FIG. 14 is a flowchart of a method of generating a layout plan for a semiconductor device, in accordance with some embodiments.

FIG. 15 is a block diagram of an electronic design automation (EDA) system, in accordance with some embodiments.

FIG. 16 is a block diagram of an integrated circuit (IC) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B and C), and does not mean one element from A, one element from B, and one element from C, unless otherwise described.

In some applications, a semiconductor device based on a back-side power delivery network (BSPDN) configuration includes conductive tracks for power supply at a back-side of the substrate with the benefits of wider conductive tracks for power supply and smaller cell sizes at the front-side of the substrate. In some applications, with the reduced cell sizes (e.g., cell heights), some features of a circuit cell may be too close, such that these features can be practically manufactured only based on applying a more complicated lithographic process and/or introducing additional masks, which correspond to increased manufacturing costs and/or decreased yield rate.

In some embodiments, according to the present application, by imposing constraints and/or guidelines such that the via patterns adjacent to a cell boundary are limited within an area having a zip-zag pattern. Accordingly, a via pitch of these via patterns is effectively enlarged without increasing the cell height. In some embodiments, a semiconductor device and the corresponding layout plan based on one or more embodiments of the present disclosure would reduce or eliminate the necessity of applying a more complicated lithographic process and/or introducing additional masks, which correspond to reduced manufacturing costs and/or increased yield rate.

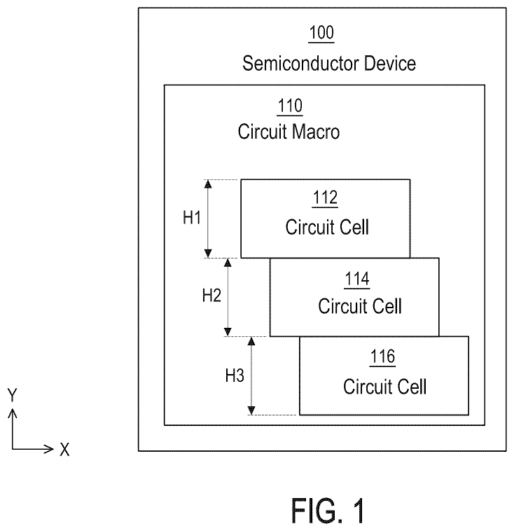

FIG. 1 is a block diagram of a semiconductor device 100, in accordance with some embodiments of the present disclosure. In some embodiments, semiconductor device 100 corresponds to an IC device or a portion of the IC device.

As in FIG. 1, semiconductor device 100 includes, among other things, at least one circuit macro 110. In some embodiments, circuit macro 110 corresponds to a set of semiconductor components configured as a memory, a controller, one or more logic gates, or the like. Circuit macro 110 includes, among other things, one or more circuit cells, such as circuit cell 112, circuit cell 114, and circuit cell 116. In some embodiments, each one of circuit cells 112, 114, and 116 corresponds to one or more layout cells including layout patterns indicative of transistors formed based on one or more active regions extending along a first direction (e.g., the X direction) and one or more gate structures extending along a second direction (e.g., the Y direction). In some embodiments, each one of circuit cells 112, 114, and 116 (and the corresponding layout cells) has a corresponding cell height H1, H2, and H3 measurable along the second direction.

In some embodiments, each one of the layout cells of circuit cells 112, 114, and 116 includes layout patterns indicative of respective conductive lines within one or more metallization layers and electrically connecting various transistors of circuit cells 112, 114, and 116. In some embodiments, the semiconductor device 100 defines multiple power track regions extending along the first direction configured to carry a first supply voltage (e.g., VDD) or a second supply voltage (e.g., VSS or ground). In some embodiments, a circuit cell includes a first side extending along a power track region and a second side extending along another power track region. In some embodiments, a circuit cell that does not have any other power track region between the first side and the second side thereof is sometimes referred to as having a standard cell height. In some embodiments for a more compact design based on some processing nodes, a circuit cell having a standard cell height includes up to four or five metallization regions (other than the power track regions) extending along the first direction in a lowest metallization layer (also referred to as MO layer) over the transistors of the circuit cell. In some embodiments, any of cell height H1, H2, and H3 has a standard cell height (e.g., a 1H cell), two standard cell heights (e.g., a 2H cell), or three standard cell heights (e.g., a 3H cell). In some embodiments, a circuit cell in circuit macro 110 corresponds to multiple standard cell heights or less than one standard cell height (e.g., a 1/2H cell).

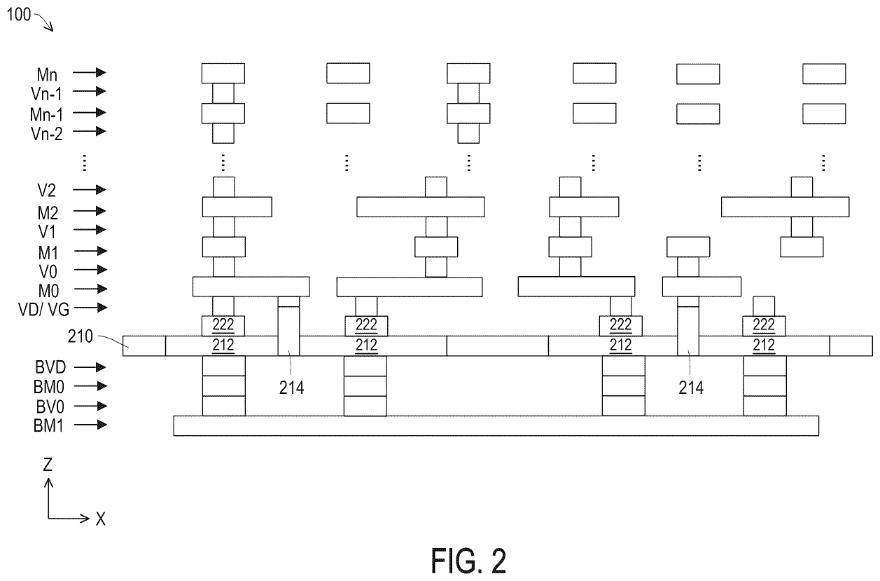

FIG. 2 is a cross-sectional view of a semiconductor device (e.g., semiconductor device 100), in accordance with some embodiments. In some embodiments, the cross-sectional view is a simplified cross-sectional view, with many features simplified or not depicted.

Semiconductor device 100 in FIG. 2 includes a substrate 210 with active regions 212 and gate structures 214 formed at least partially in substrate 210. In this example, semiconductor device 100 includes metal-to-drain/source (MD) structures 222 coupled to the active regions 212. In this example, semiconductor device 100 includes via-to-drain/source (VD) structures coupled to MD structures 222 and via-to-gate (VG) structures coupled to gate structures 214 at a VD/VG layer above substrate 210 (with respect to a direction Z). In some embodiments, semiconductor device 100 further includes a plurality of metallization layers (e.g., M0, M1, M2, . . . , Mn-1, and Mn layers) and a plurality of via layers (e.g., V0, V1, V2, . . . , Vn-2, and Vn-1 layers) over the VD/VG layer and substrate 210 (n being a positive integer). In some embodiments, a number of metallization layers over substrate 210 ranges from 8 to 14. In some embodiments, Vn-1 layer denotes the via structures between and connecting conductive lines in Mn-1 layer and Mn layer. In some embodiments, M0 layer denotes the first metallization layer above substrate 210. In some embodiments, the plurality of metallization layers and the plurality of via layers include a conductive material including copper, aluminum, gold, tungsten, a combination thereof, or the like.

Semiconductor device 100 in FIG. 2, as a non-limiting example, further includes conductive structures disposed under substrate 210. For example, semiconductor device 100 further includes backside metallization layers BM0 and BM1 and backside via layers BVD and BV0. In this example, BVD layer denotes backside via structures between and connecting active regions 212 and backside conductive lines in BM0 layer; and BV0 layer denotes backside via structures between and connecting backside conductive lines in BM0 layer and BM1 layer. In some embodiments, BM0 layer denotes the first metallization layer under substrate 210. In this example, there are two backside metallization layers and corresponding via layers. In some embodiments, a number of backside metallization layers under substrate 210 ranges from 2 to 6. In some embodiments, a portion or all of the backside conductive structures (e.g., backside metallization layers BM0 and BM1 and backside via layers BVD and BV0) are at least partially embedded in substrate 210. In some embodiments, backside metallization layers BM0 and BM1 and backside via layers BVD and BV0 include a conductive material including copper, aluminum, gold, tungsten, a combination thereof, or the like. In some other embodiments, a semiconductor device does not include any backside conductive structures.

In some embodiments, semiconductor device 100 includes one or more redistribution layers and conductive pad structures (not in FIG. 2) over the one or more redistribution layers. In some embodiments, semiconductor device 100 further includes conductive terminal structures (e.g., conductive bumps, copper pillar bumps, solder bumps, or the like, not in FIG. 2) over the conductive pad structures. In some embodiments, semiconductor device 100 also includes one or more backside redistribution layers and backside conductive pad structures (not in FIG. 2) under the one or more backside redistribution layers. In some embodiments, semiconductor device 100 also includes backside conductive terminal structures (e.g., conductive bumps, copper pillar bumps, solder bumps, or the like, not in FIG. 2) under the backside conductive pad structures.

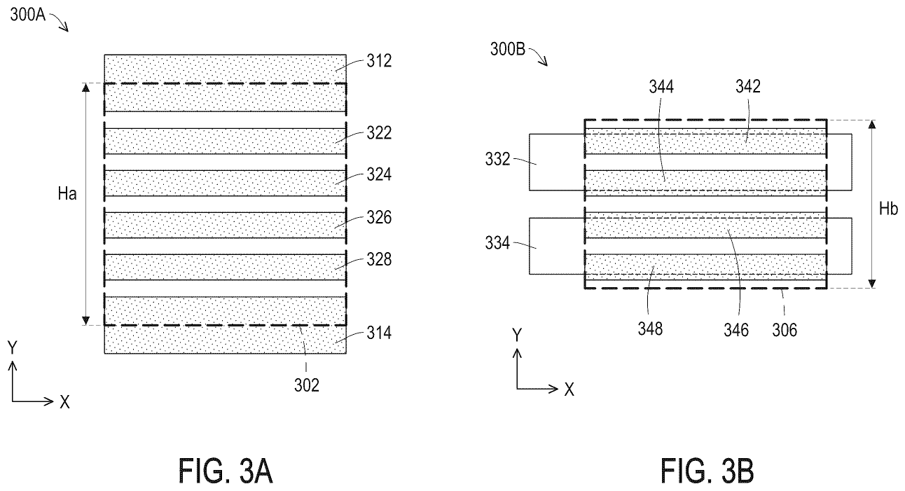

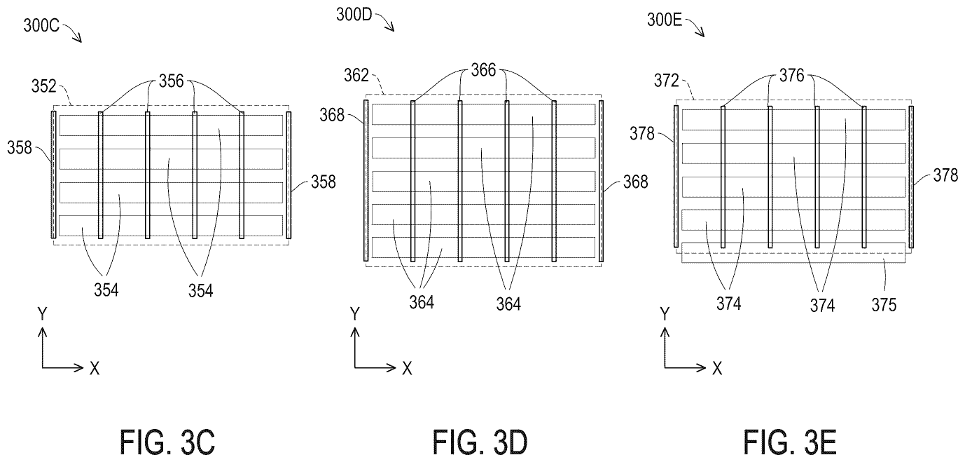

FIG. 3A is a layout diagram of a first layout cell example 300A, in accordance with some embodiments. FIG. 3A shows only a portion of first layout cell 300A as a non-limiting example. In FIG. 3A, first layout cell 300A corresponds to a first circuit cell and has a cell boundary 302. First layout cell 300A has metallization regions 312, 314, 322, 324, 326, and 328 extending along a first direction (e.g., the X direction) and arranged one next to another along a second direction (e.g., the Y direction) in a lowest metallization layer (e.g., the M0 layer in FIG. 2) above a substrate (also referred to as at a front-side of a resulting semiconductor device).

In some embodiments, layout patterns in metallization regions 312 and 314 indicating conductive lines for carrying power supply voltages (e.g., VDD, VSS, or ground). In some embodiments, layout patterns in metallization regions 322, 324, 326, and 328 indicating conductive lines for connecting various elements of the first circuit cell. In some embodiments, a power network based on having the metallization regions 312 and 314 for power supply at the M0 layer is also referred to as a front-side power delivery network (FSPDN) configuration. In FIG. 3A, first layout cell 300A has a first standard cell heigh Ha along the second direction for accommodating metallization regions 312, 314, 322, 324, 326, and 328.

FIG. 3B is a layout diagram of a second layout cell example 300B, in accordance with some embodiments. FIG. 3B shows only a portion of second layout cell 300B as a non-limiting example. In FIG. 3B, second layout cell 300B corresponds to a second circuit cell and has a cell boundary 306. Second layout cell 300A has metallization regions 332, 334, 342, 344, 346, and 348 extending along a first direction (e.g., the X direction). Metallization regions 342, 344, 346, and 348 are arranged one next to another along a second direction (e.g., the Y direction) in a lowest metallization layer (e.g., the M0 layer in FIG. 2) above a substrate (also referred to as at a front-side of a resulting semiconductor device). Moreover, metallization regions 332 and 334 are arranged in a metallization layer (e.g., the BM0 layer in FIG. 2) under the substrate (also referred to as at a back-side of the resulting semiconductor device). In some embodiments, metallization regions 342, 344, 346, and 348 have a line width along the second direction and a line pitch along the second direction comparable or the same as those of metallization regions 322, 324, 326, and 328 in FIG. 3A.

In some embodiments, layout patterns in metallization regions 332 and 334 indicating conductive lines for carrying power supply voltages (e.g., VDD, VSS, or ground). In some embodiments, layout patterns in metallization regions 342, 344, 346, and 348 indicating conductive lines for connecting various elements of the second circuit cell. In some embodiments, a power network based on having the metallization regions 332 and 334 for power supply at the BM0 layer is also referred to as a back-side power delivery network (BSPDN) configuration. In FIG. 3B, second layout cell 300B has a second standard cell heigh Hb along the second direction for accommodating metallization regions 342, 344, 346, and 348. Compared to first layout cell 300A having the metallization regions 312 and 314 for power supply at the front-side, by having the metallization regions 332 and 334 for power supply at the back-side, the second standard cell heigh Hb is less than the first standard cell heigh Ha. Accordingly, a standard cell based on the BSPDN configuration has a smaller cell height and wider back-side metallization regions than its counterpart based on the FSPDN configuration.

FIG. 3C is a layout diagram of a third layout cell example 300C, in accordance with some embodiments. FIG. 3C shows only a portion of third layout cell 300C as a non-limiting example. In FIG. 3C, third layout cell 300C corresponds to a third circuit cell based on the BSPDN configuration, and the metallization regions at the back-side for power supply are not depicted in FIG. 3C. In FIG. 3C, third layout cell 300C has a cell boundary 352 and four metallization regions 354 extending along a first direction (e.g., the X direction) in a lowest metallization layer (e.g., M0 layer). In some embodiments, third layout cell 300C is also referred to as a layout cell of 4 M0. Moreover, third layout cell 300C further includes gate patterns 356 indicative of gate structures within cell boundary 352 and dummy gate patterns 358 indicative of dummy gate structures on the left segment and the right segment (opposite sides with respect to X direction) of cell boundary 352.

In FIG. 3C, none of metallization regions 354 overlaps the upper segment and the lower segment (opposite sides with respect to Y direction) of cell boundary 352. As such, the upper side of third layout cell 300C is suitable for abutting another layout cell that does not have a metallization region in the lowest metallization layer (e.g., M0 layer) overlapping the lower segment of the cell boundary of such other layout cell, and thus defining a shared space along the upper segment of cell boundary 352. Also, the lower side of third layout cell 300C is suitable for abutting another layout cell that does not have a metallization region in the lowest metallization layer (e.g., M0 layer) overlapping the upper segment of the cell boundary of such other layout cell, and thus defining a shared space along the lower segment of cell boundary 352.

FIG. 3D is a layout diagram of a fourth layout cell example 300D, in accordance with some embodiments. FIG. 3D shows only a portion of fourth layout cell 300D as a non-limiting example. In FIG. 3D, fourth layout cell 300D corresponds to a fourth circuit cell based on the BSPDN configuration, and the metallization regions at the back-side for power supply are not depicted in FIG. 3D. In FIG. 3D, fourth layout cell 300D has a cell boundary 362 and five metallization regions 364 extending along a first direction (e.g., the X direction) in a lowest metallization layer (e.g., M0 layer). In some embodiments, fourth layout cell 300D is also referred to as a layout cell of 5 M0. Moreover, fourth layout cell 300D further includes gate patterns 366 indicative of gate structures within cell boundary 362 and dummy gate patterns 368 indicative of dummy gate structures on the left segment and the right segment (opposite sides with respect to X direction) of cell boundary 362.

In FIG. 3D, similar to the example in FIG. 3C, none of metallization regions 364 overlaps the upper segment and the lower segment (opposite sides with respect to Y direction) of cell boundary 362. As such, the upper side of fourth layout cell 300D is suitable for abutting another layout cell and defining a shared space along the upper segment of cell boundary 362. Also, the lower side of fourth layout cell 300D is suitable for abutting another layout cell and defining a shared space along the lower segment of cell boundary 362.

FIG. 3E is a layout diagram of a fifth layout cell example 300E, in accordance with some embodiments. FIG. 3E shows only a portion of fifth layout cell 300E as a non-limiting example. In FIG. 3E, fifth layout cell 300E corresponds to a fifth circuit cell based on the BSPDN configuration, and the metallization regions at the back-side for power supply are not depicted in FIG. 3E. In FIG. 3E, fifth layout cell 300E has a cell boundary 372, four metallization regions 374 extending along a first direction (e.g., the X direction) in a lowest metallization layer (e.g., M0 layer) within cell boundary 372, and one metallization region 375 in the lowest metallization layer and extending along a lower segment of cell boundary 372. In some embodiments, fifth layout cell 300E is also referred to as a layout cell of 4.5 M0. Moreover, fifth layout cell 300E further includes gate patterns 376 indicative of gate structures within cell boundary 372 and dummy gate patterns 378 indicative of dummy gate structures on the left segment and the right segment (opposite sides with respect to X direction) of cell boundary 372.

In FIG. 3E, none of metallization regions 374 overlaps the upper segment of cell boundary 372. As such, the upper side of fifth layout cell 300E is suitable for abutting another layout cell and defining a shared space along the upper segment of cell boundary 372. However, metallization region 375 overlaps the lower segment of cell boundary 372. As such, the lower side of fifth layout cell 300E is suitable for abutting another layout cell that has a metallization region overlapping an upper segment of the cell boundary of such other layout cell, and thus defining a shared metallization region along the lower segment of cell boundary 372.

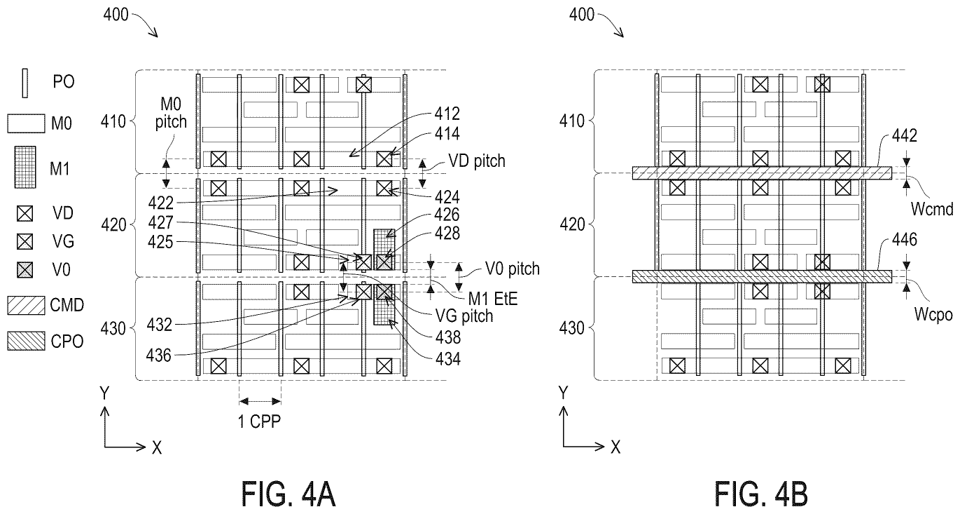

FIGS. 4A and 4B are layout diagrams of different portions of a first layout plan example 400, in accordance with some embodiments. Layout patterns in FIGS. 4A and 4B only constitute a portion of first layout plan 400 as non-limiting examples. Other layout cells and layout patterns of first layout plan 400 are omitted in FIGS. 4A and 4B.

FIG. 4A includes legends of various types of layout patterns used in FIGS. 4A and 4B. In FIGS. 4A and 4B, the layout patterns include layout patterns for poly silicon gate (PO) patterns indicative of polysilicon gate structures. In some embodiments, the polysilicon gate structures are used as functional gate structures, dummy gate structures, or placeholder structures on which functional structures and dummy structures are formed. In this non-limiting example, the PO patterns are spaced apart from one another by a contacted poly pitch (1 CPP, also known as a gate pitch) along a first direction (e.g., the X direction).

In FIGS. 4A and 4B, the layout patterns include M0 layout patterns for conductive lines at a lowest metallization layer (e.g., M0 layer) above the gate structures, M1 layout patterns for conductive lines at another metallization layer above the lowest metallization layer (e.g., M1 layer), VD layout patterns for via structures connecting drain/source terminals to corresponding conductive lines at the M0 layer, VG layout patterns for via structures connecting gate structures to corresponding conductive lines at the M0 layer, and V0 layout patterns for via structures connecting conductive lines at the M0 layer and corresponding conductive lines at the M1 layer. The legends in FIG. 4A further indicate a CMD layout pattern indicative of removal of materials for defining drain/source terminals, and a CPO layout pattern indicative of removal of materials for defining gate structures, which are used in FIG. 4B.

In FIGS. 4A-4B, first layout plan 400 includes three layout cells 410, 420, and 430 stacked one over another in a second direction (e.g., the Y direction). Each of layout cells 410, 420, and 430 is based on the BSPDN configuration including conductive lines at a back-side of the resulting semiconductor device for power supply, and including conductive lines at M0 layer (indicated by M0 layout patterns) at a front-side of the resulting semiconductor device within four conductive regions extending along the first direction (e.g., the X direction).

In FIG. 4A, layout cell 410 abuts layout cell 420. Layout cell 410 includes a conductive line pattern 412 indicative of a conductive line in a metallization region of M0 layer, and includes via patterns (e.g., via pattern 414) indicative of via structures under M0 layer and configured to connect corresponding drain/source terminals with the conductive line indicated by conductive line pattern 412. Layout cell 420 includes a conductive line pattern 422 indicative of a conductive line in a metallization region of M0 layer, and includes via patterns (e.g., via pattern 424) indicative of via structures under M0 layer and configured to connect corresponding drain/source terminals with the conductive line indicated by conductive line pattern 422. In some embodiments, conductive line pattern 412 and conductive line pattern 422 are disposed based on a metallization pitch (M0 pitch) along the second direction.

In FIG. 4A, layout cell 420 abuts layout cell 430. Layout cell 420 includes a conductive line pattern 425 indicative of a conductive line in another metallization region of M0 layer, a conductive line pattern 426 indicative of a conductive line in a metallization region of M1 layer, a via pattern 427 indicative of a via structure between the conductive line indicated by conductive line pattern 425 at a corresponding PO pattern, and a via pattern 428 indicative of a via structure between the conductive line indicated by conductive line pattern 425 at M0 layer and the conductive line indicated by conductive line pattern 426 at M1 layer.

Layout cell 430 includes a conductive line pattern 432 indicative of a conductive line in yet another metallization region of M0 layer, a conductive line pattern 434 indicative of a conductive line in another metallization region of M1 layer, a via pattern 436 indicative of a via structure between the conductive line indicated by conductive line pattern 432 at a corresponding PO pattern, and a via pattern 438 indicative of a via structure between the conductive line indicated by conductive line pattern 432 at M0 layer and the conductive line indicated by conductive line pattern 424 at M1 layer. In some embodiments, conductive line pattern 425 and conductive line pattern 432 are disposed based on the same metallization pitch as M0 pitch between conductive line pattern 412 and conductive line pattern 422.

In this non-limiting example, via pattern 414 and via pattern 424 face each other across a cell boundary between layout cell 410 and layout cell 420, are aligned with each other in the second direction (e.g., the Y direction), and are arranged based on a via pitch (referred to and labeled “VD pitch”). In this non-limiting example, via pattern 427 and via pattern 436 face each other across the cell boundary, are aligned with each other in the second direction, and are arranged based on a via pitch (referred to and labeled “VG pitch”). In this non-limiting example, via pattern 428 and via pattern 434 face each other across the cell boundary, are aligned with each other in the second direction, and are arranged based on a via pitch (referred to and labeled “V0 pitch”). Also, conductive line pattern 426 and conductive line pattern 434 are spaced apart by an end-to-end distance (referred to and labeled “M1 EtE”).

In the non-limiting example in FIG. 4A, based on the BSPDN configuration, there are no metallization regions for power supply at M0 layer between layout cell 410 and layout cell 420 and between layout cell 420 and layout cell 430. As such, the cell height and/or the placement density of cells in the second direction (e.g., the Y direction) is limited by the capability of the manufacturing process with respect to the minimum sizes of VD pitch, VG pitch, V0 pitch, and M1 EtE. In this example, the via pitch (VD pitch, VG pitch, or V0 pitch) equals the metallization pitch (M0 pitch). In some embodiments, to reduce the cell height, the minimum sizes of VD pitch, VG pitch, V0 pitch, and M1 EtE would be so small (e.g., less than 20 nanometers, nm) that the corresponding structures are realizable based on applying a more complicated lithographic process and/or introducing additional masks, which correspond to increased manufacturing costs and/or decreased yield rate.

In FIG. 4B, first layout plan 400 includes a CMD pattern 442 shared by layout cell 410 and layout cell 420 and indicative of removal of materials for defining drain/source terminals. In FIG. 4B, first layout plan 400 further includes a CPO pattern 446 shared by layout cell 420 and layout cell 430 and indicative of removal of materials for defining gate structures. In the non-limiting example in FIG. 4B, based on the BSPDN configuration, the cell height and/or the placement density of cells in the second direction is also limited by the capability of the removal process with respect to the minimum sizes of the CMD pattern width (e.g., width Wcmd) and the CMO pattern width (e.g., width Wcpo).

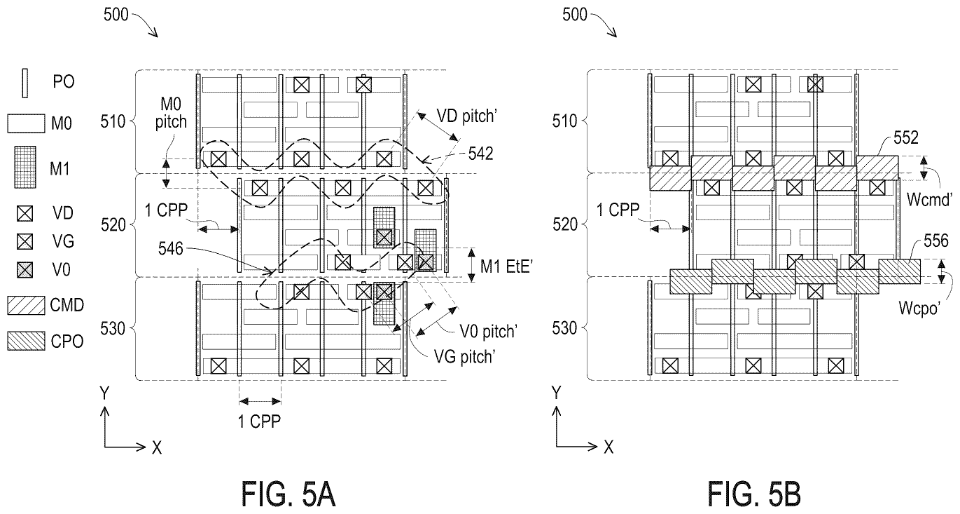

FIGS. 5A-5B are layout diagrams of different portions of a second layout plan example 500, in accordance with some embodiments. Layout patterns in FIGS. 5A and 5B only constitute a portion of second layout plan 500 as non-limiting examples. Other layout cells and layout patterns of second layout plan 500 are omitted in FIGS. 5A and 5B. FIG. 5A includes legends of various types of layout patterns used in FIGS. 5A and 5B, which are the same as the legends presented in FIG. 4A, and detailed description thereof is thus omitted.

In FIGS. 5A and 5B, second layout plan 500 includes three layout cells 510, 520, and 530 stacked one over another in a second direction (e.g., the Y direction). In some embodiments, layout cells 510, 520, and 530 correspond to layout cells 410, 420, and 430 in FIGS. 4A and 4B. In this non-limiting example, compared to first layout plan 400 in FIGS. 4A and 4B, layout cell 520 is shifted toward the first direction (e.g., the X direction) by 1 CPP.

In FIG. 5A, layout cell 510 and layout cell 520 includes VD patterns adjacent to the cell boundary between layout cell 510 and layout cell 520. As layout cell 520 is shifted with respect to layout cell 510 by 1 CPP, the VD patterns adjacent to the cell boundary are within a first area 542 having a first zig-zag pattern along the cell boundary. Compared to first layout plan 400, the VD patterns adjacent to the cell boundary have a via pitch (labeled as VD pitch′) that is greater than a metallization pitch (M0 pitch) between two M0 patterns adjacent to the cell boundary. In this example, the via pitch (VD pitch′) is the square root of the summation of (i) the square of metallization pitch (M0 pitch) and (ii) the square of 1 CPP.

In FIG. 5A, layout cell 520 and layout cell 530 includes VG patterns adjacent to the cell boundary between layout cell 520 and layout cell 530, and V1 patterns adjacent to the cell boundary between layout cell 520 and layout cell 530. As layout cell 520 is shifted with respect to layout cell 530 by 1 CPP, the VG patterns adjacent to the cell boundary are within a second area 546 having a second zig-zag pattern along the cell boundary. Compared to first layout plan 400, the VG patterns adjacent to the cell boundary have a via pitch (labeled as VG pitch′) that is greater than a metallization pitch (M0 pitch). In this example, the via pitch (VG pitch′) is the square root of the summation of (i) the square of metallization pitch (M0 pitch) and (ii) the square of 1 CPP. Similarly, the V0 patterns adjacent to the cell boundary have a via pitch (labeled as V0 pitch′) that is greater than the metallization pitch (M0 pitch). In some embodiments, VD pitch′, VG pitch′, and/or V0 pitch′ are one of at least two times the metallization pitch (e.g., M0 pitch) or at least the gate pitch (e.g., 1 CPP). In some embodiments, M1 patterns in layout plan 500 that are aligned along the second direction are spaced apart by an end-to-end distance (labeled as M1 EtE′) that is greater than M1 EtE in FIG. 4A. In some embodiments, the end-to-end distance (M1 EtE′) is also greater than the metallization pitch (M0 pitch).

In the non-limiting example in FIG. 5A, based on the BSPDN configuration, there are no metallization regions for power supply at M0 layer between layout cell 510 and layout cell 520 and between layout cell 520 and layout cell 530. Based on arranging the VD patterns and/or VG patterns along a cell boundary within an area of a zig-zag pattern, the via pitch of the VD patterns and/or VG patterns (VD pitch′ and VG pitch′), as well as V0 pitch′ and/or M1 EtE′ according to the example in FIG. 5A, are enlarged compared to the example in FIG. 4A. In some embodiments, to reach the same cell height, the enlarged sizes of VD pitch′, VG pitch′, V0 pitch′, and/or M1 EtE′ would reduce or eliminate the necessity of applying a more complicated lithographic process and/or introducing additional masks, which correspond to reduced manufacturing costs and/or increased yield rate compared to the example in FIG. 4A.

In FIG. 5B, second layout plan 500 includes a CMD pattern 552 shared by layout cell 510 and layout cell 520 and indicative of removal of materials for defining drain/source terminals. In FIG. 5B, second layout plan 500 further includes a CPO pattern 556 shared by layout cell 520 and layout cell 530 and indicative of removal of materials for defining gate structures. By shifting VD patterns and VG patterns as in FIG. 5A, widths of CMD pattern 552 and CPO pattern 556 (Wcmd′ and Wcpo′) are increased at different portions along the corresponding cell boundaries without impacting the functionality of corresponding drain/source terminals and gate structures. The resulting CMD pattern 552 and CPO pattern 556 have respective zig-zag patterns along the corresponding cell boundaries. In the non-limiting example in FIG. 5B, based on the BSPDN configuration, the restriction on the cell height and/or the placement density of cells is relaxed compared to the example in FIGS. 4A and 4B based on the increased sizes of the CMD pattern width (e.g., width Wcmd′) and the CMO pattern width (e.g., width Wcpo′). In some embodiments, the CMD pattern width (e.g., width Wcmd′) and the CMO pattern width (e.g., width Wcpo′) are greater than the metallization pitch (e.g., M0 pitch), and are the same or within 10% of variations.

Layout plan 500 in FIGS. 5A and 5B is illustrated as a non-limiting example. In some embodiments, the VD patterns and/or the VG patterns of neighboring layout cells are placed within corresponding areas of zig-zag pattern with or without misaligned layout cells, depending on how the layout cells are prepared as standard cells in the cell library and how the placement sites for placing the layout cells are arranged.

Therefore, according to one or more embodiments of the present disclosure, a semiconductor device manufactured based on the BSPDN configuration in view of the example of FIGS. 5A and 5B includes a first circuit cell and a second circuit cell abutting the first circuit cell. In some embodiments, the first circuit cell includes first one or more conductive lines in a first metallization line region of a first metallization layer (e.g., M0 layer) and includes first one or more via structures under the first metallization layer. In some embodiments, the second circuit cell includes second one or more conductive lines in a second metallization line region of the first metallization layer (e.g., M0 layer) and includes second one or more via structures under the first metallization layer. In some embodiments, the first metallization line region and the second metallization line region are along the cell boundary. In some embodiments, based on the first one or more via structures being between the first metallization layer and first one or more drain/source conductive structures of the first circuit cell (i.e., via structures of the VD layer) and the second one or more via structures being between the first metallization layer and second one or more drain/source conductive structures of the second circuit cell (i.e., via structures of the VD layer), the first one or more via structures and the second one or more via structures are within a first area (e.g., as indicated by first area 542) having a first zig-zag pattern along the cell boundary. In some embodiments, based on the first one or more via structures being between the first metallization layer and first one or more gate structures of the first circuit cell (i.e., via structures of the VG layer) and the second one or more via structures being between the first metallization layer and second one or more gate structures of the second circuit cell (i.e., via structures of the VG layer), the first one or more via structures and the second one or more via structures are within a second area (e.g., as indicated by second area 546) having a second zig-zag pattern along the cell boundary.

In some embodiments, the cell boundary extends along a first direction (e.g., the X direction), the first metallization line region and the second metallization line region are disposed based on a metallization pitch (e.g., M0 pitch) along a second direction (e.g., the Y direction) different from the first direction. In some embodiments, based on the first one or more via structures being between the first metallization layer and the first one or more drain/source conductive structures of the first circuit cell (i.e., via structures of the VD layer) and the second one or more via structures being between the first metallization layer and the second one or more drain/source conductive structures of the second circuit cell (i.e., via structures of the VD layer), the first one or more via structures and the second one or more via structures are disposed based on a first minimum via pitch (e.g., VD pitch′) that is greater than the metallization pitch (e.g., M0 pitch). In some embodiments, based on the first one or more via structures being between the first metallization layer and the first one or more gate structures of the first circuit cell (i.e., via structures of the VG layer) and the second one or more via structures being between the first metallization layer and the second one or more gate structures of the second circuit cell (i.e., via structures of the VG layer), the first one or more via structures and the second one or more via structures are disposed based on a second minimum via pitch (e.g., VG pitch′) that is greater than the metallization pitch (e.g., M0 pitch).

In some embodiments, the first circuit cell further includes third one or more via structures (i.e., via structures of V0 layer) between the first metallization line region and a third metallization line region of a second metallization layer above the first metallization layer, and the second circuit cell further includes fourth one or more via structures (i.e., via structures of V0 layer) between the second metallization line region and a fourth metallization line region of the second metallization layer. In some embodiments, the third one or more via structures are spaced apart from the fourth one or more via structures based on at least a third minimum via pitch (e.g., V0 pitch′) that is greater than the metallization pitch (e.g., M0 pitch′).

In some embodiments, the first circuit cell further includes a third conductive line of the second metallization layer (e.g., M1 layer), the second circuit cell further includes a fourth conductive line of the second metallization layer, and the third conductive line and the fourth conductive line are aligned along the second direction (e.g., the Y direction). In some embodiments, the third conductive line and the fourth conductive line are disposed based on a minimum end-to-end distance (e.g., M1 EtE′) that is along the second direction and is greater than the metallization pitch (e.g., M0 pitch).

In some embodiments, the first one or more drain/source conductive structures and the second one or more drain/source conductive structures are spaced apart based on a CMD pattern (e.g., CMD pattern 552), which has a third zig-zag pattern along the cell boundary. In some embodiments, the first one or more gate structures and the second one or more gate structures are spaced apart based on a CPO pattern (e.g., PO pattern 556), which has a fourth zig-zag pattern along the cell boundary.

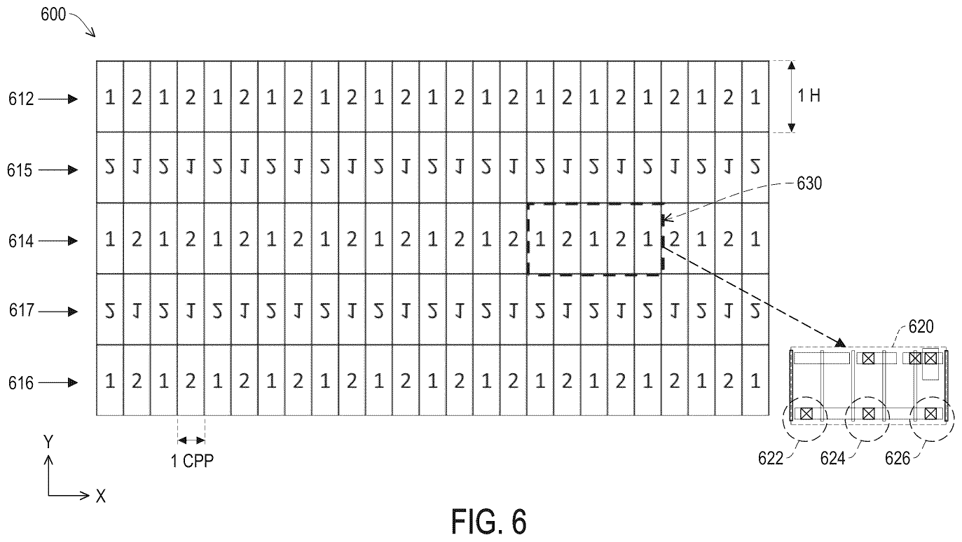

FIG. 6 is a diagram of a plurality of placement sites 600 of a layout plan for a semiconductor device, in accordance with some embodiments. In FIG. 6, each rectangular box with a numeral 1, 2, vertically flipped 1, or vertically flipped 2 represents a placement site of corresponding placement types. In some embodiments, each one of the plurality of placement sites of the layout plan has a width along a first direction (e.g., the X direction) corresponding to a gate pitch (e.g., 1 CPP) of the layout plan and a height along a second direction (e.g., the Y direction) corresponding to a standard cell height (e.g., 1H) of the layout plan.

In FIG. 6, the plurality of placement sites 600 includes rows of placement sites, such as rows 612, 614, 615, 616, and 617. In this example, rows 612, 614, and 616 include placement sites of a first placement type (labeled with numeral 1) and placement sites of a second placement type (labeled with numeral 2) arranged in an alternative manner along the first direction (e.g., the X direction) and usable for placing a standard layout cell of the standard cell height in a nominal form (e.g., the orientation as stored in a cell library). Also, rows 615 and 617 include placement sites of a flipped first placement type (labeled with flipped 1) and placement sites of a flipped second placement type (labeled with flipped 2) arranged in an alternative manner along the first direction (e.g., the X direction) and usable for placing the standard layout cell in a flipped form that corresponds to mirroring the nominal form about an axis along the first direction.

In this example, the placement sites of the first placement type (labeled with numeral 1) in a row abut the placement sites of the flipped second placement type (labeled with flipped 2) in a neighboring row; and the placement sites of the second placement type (labeled with numeral 2) in a row abut the placement sites of the flipped first placement type (labeled with flipped 1) in a neighboring row. As such, the plurality of placement sites 600 includes first placement type/flipped first placement type and second placement type/flipped second placement type arranged in a checkerboard-like manner.

In some embodiments, the first placement type indicates accommodating a via pattern (e.g., VD pattern or VG pattern) under the first metallization layer of the layout plan to be disposed adjacent to a reversed second direction side (e.g., also referred to and depicted as the left side in FIG. 6) of a corresponding placement site. In some embodiments, the second placement type indicates prohibiting any via pattern (e.g., VD pattern or VG pattern) under the first metallization layer of the layout plan disposed adjacent to the reversed second direction side (e.g., also referred to and depicted as the left side in FIG. 6) of the corresponding placement site. In the non-limiting example in FIG. 6, the first placement type and the second placement type are defined based on VD patterns.

In FIG. 6, for placing a target layout cell 620 that has a cell height of 1H and cell width of 5 CPP, a set of placement sites 630 that includes five consecutive placement sites in a same row (e.g., row 614) is identified for placing target layout cell 620. For example, the target layout cell 620 includes VD patterns 622, 624, and 626 at the bottom thereof at the first, third, and fifth regions defined by gate patterns, and thus is configured to be placed at five consecutive placement sites with placement type labels [1, 2, 1, 2, 1].

In some embodiments, each circuit cell includes a plurality of candidate layout cells associated therewith for placement with the left-most edge site being the first placement type, the flipped first placement type, the second placement type, and the flipped second placement. In some embodiments, one of the plurality of candidate layout cells associated with the circuit cell is selected as the target layout cell at the set of placement sites based on a placement site type of an edge placement site of the set of placement sites in a reversed first direction (e.g., the left-most edge site). For example, the target layout cell 620 is determinable based on the left-most edge placement site of the set of placement sites is of the first placement type (labeled with numeral 1). Based on the checkerboard-like arrangement of the plurality of placement sites and the pre-designed candidate layout cells, the placement constraints or guidelines based on zig-zag patterns for various features as illustrated in FIGS. 5A and 5B are incorporable into an electronic design automation (EDA) tool for efficient and/or automated cell placement.

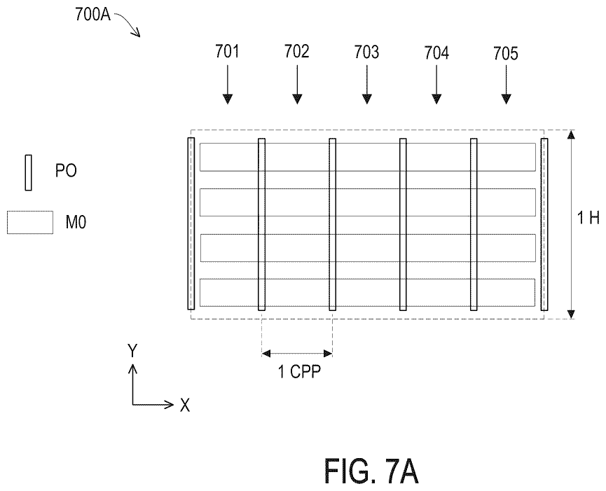

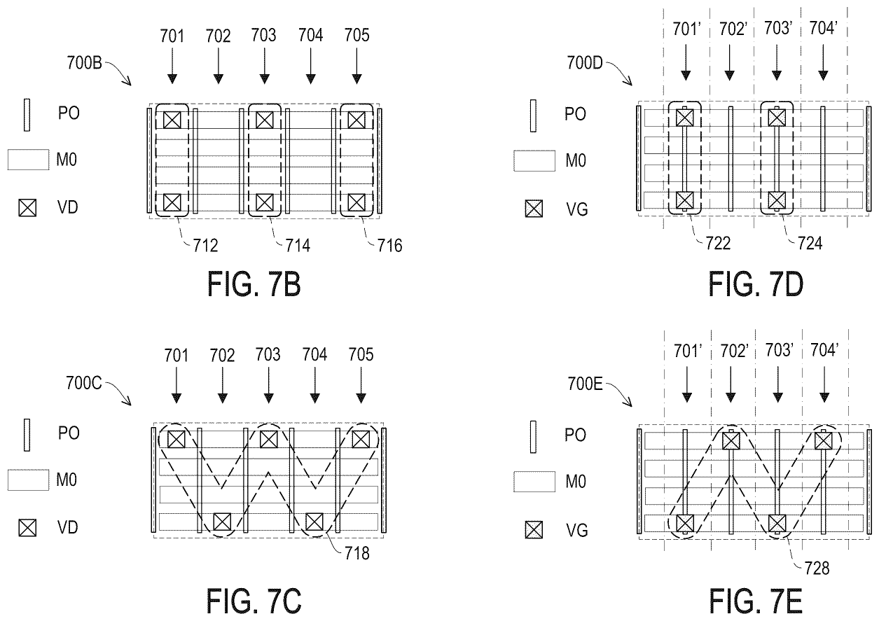

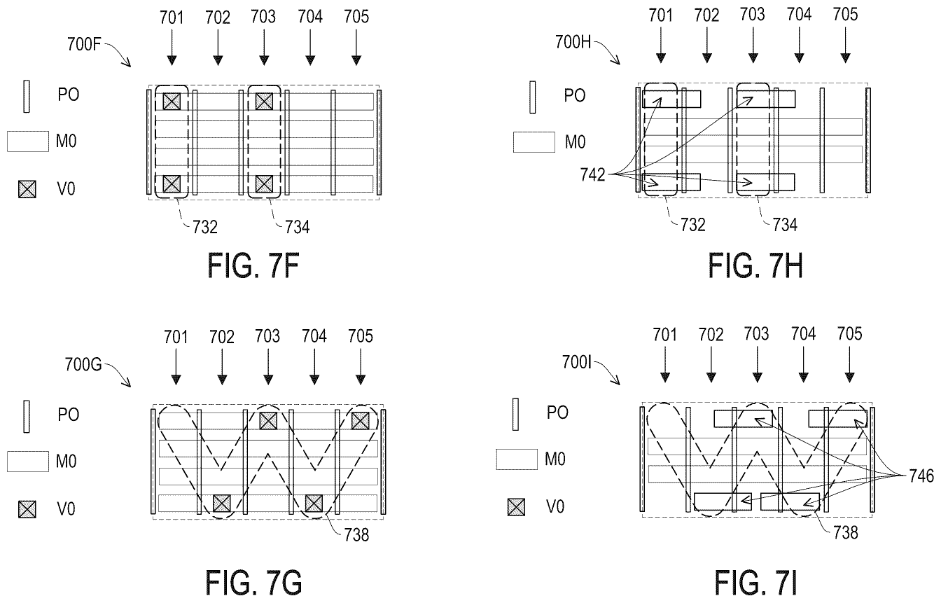

FIGS. 7A-12E correspond to non-limiting examples of candidate layout cells for various circuit cells. There may be one or more other approaches for preparing the candidate layout cells to be used in conjunction with the checkerboard-like arrangement of the plurality of placement sites in FIG. 6 to meet the constraints and guidelines in FIGS. 5A and 5B. FIGS. 7A-7I, 10B-10D, and 11B-11C include legends of various types of layout patterns that are the same as the legends presented in FIG. 4A, and detailed description thereof is thus omitted.

FIG. 7A is a layout diagram of a portion of a base layout cell example 700A, in accordance with some embodiments. In FIG. 7A, base layout cell 700A includes PO patterns and M0 regions for conductive line patterns at M0 layer, as indicated by the legends. In this non-limiting example, base layout cell 700A has a cell width along a first direction (e.g., the X direction) of 5 CPP and a cell height along a second direction (e.g., the Y direction) of 1H, where CPP corresponds to a gate pitch and H corresponds to a standard cell height as illustrated above. In this non-limiting example, base layout cell 700A occupies five layout regions 701, 702, 703, 704, and 705 defined by adjacent PO patterns, where each one of the layout regions has a height of 1H and a width of 1 CPP and corresponds to a placement site in FIG. 6.

FIG. 7B is a layout diagram of a portion of a first layout cell example 700B based on base layout cell 700A of FIG. 7A, in accordance with some embodiments. In FIG. 7B, first layout cell 700B includes PO patterns and M0 regions for conductive line patterns at M0 layer, as indicated by the legends. In FIG. 7B, first layout cell 700B further includes VD pattern candidates at layout region 701 at both the upper portion and the bottom portion of layout region 701; VD pattern candidates at layout region 703 at both the upper portion and the bottom portion of layout region 703; and VD pattern candidates at layout region 705 at both the upper portion and the bottom portion of layout region 705. Therefore, each one of layout regions 701, 703, and 705 is based on accommodating VD patterns adjacent to opposite sides of the layout region, while each one of layout regions 702 and 704 is based on prohibiting any VD patterns adjacent to opposite sides of the layout region. In this example, VD pattern candidates adjacent to the cell boundary are permitted within areas 712, 714, and 716 in parallel with the direction of the PO patterns. In some embodiments, a complementary counterpart of the example in FIG. 7B is defined based on first layout cell 700B such that each one of layout regions 701, 703, and 705 is based on prohibiting any VD patterns adjacent to opposite sides of the layout region, while each one of layout regions 702 and 704 is based on accommodating VD patterns adjacent to opposite sides of the layout region.

FIG. 7C is a layout diagram of a portion of a second layout cell example 700C based on base layout cell 700A of FIG. 7A, in accordance with some embodiments. In FIG. 7C, second layout cell 700C includes PO patterns and M0 regions for conductive line patterns at M0 layer, as indicated by the legends. In FIG. 7C, second layout cell 700C further includes VD pattern candidates at layout regions 701, 703, and 705 adjacent to an upper side of second layout cell 700C; and VD pattern candidates at layout regions 702 and 704 adjacent to a lower side of second layout cell 700C. Therefore, each one of layout regions 701, 703, and 705 is based on accommodating VD patterns adjacent to one side of the layout region, while each one of layout regions 702 and 704 is based on accommodating VD patterns adjacent to the other side of the layout region. In this example, VD pattern candidates adjacent to the cell boundary are permitted within area 718 that has a zig-zag pattern. In some embodiments, a complementary counterpart of the example in FIG. 7C is defined based on vertically flipping second layout cell 700C.

FIG. 7D is a layout diagram of a portion of a third layout cell example 700D based on base layout cell 700A of FIG. 7A, in accordance with some embodiments. In FIG. 7D, third layout cell 700D includes PO patterns and M0 regions for conductive line patterns at M0 layer, as indicated by the legends. In FIG. 7D, third layout cell 700D includes four layout regions 701′, 702′, 703′, and 704′ having corresponding PO patterns placed in the center thereof. In some embodiments, for the purposes of determining placement site types, layout regions 701′, 702′, 703′, and 704′ are associated with layout regions 701, 702, 703, and 704 in FIG. 7A, respectively.

In FIG. 7D, third layout cell 700D further includes VG pattern candidates at layout region 701′ at both the upper portion and the bottom portion of layout region 701′; and VG pattern candidates at layout region 703′ at both the upper portion and the bottom portion of layout region 703′. Therefore, each one of layout regions 701′ and 703′ is based on accommodating VG patterns adjacent to opposite sides of the layout region, while each one of layout regions 702′ and 704′ is based on prohibiting any VG patterns adjacent to opposite sides of the layout region. In this example, VG pattern candidates adjacent to the cell boundary are permitted within areas 722 and 724 in parallel with the direction of the PO patterns. In some embodiments, a complementary counterpart of the example in FIG. 7D is defined based on third layout cell 700D such that each one of layout regions 701′ and 703′ is based on prohibiting any VG patterns adjacent to opposite sides of the layout region, while each one of layout regions 702′ and 704′ is based on accommodating VG patterns adjacent to opposite sides of the layout region.

FIG. 7E is a layout diagram of a portion of a fourth layout cell example 700E based on base layout cell 700A of FIG. 7A, in accordance with some embodiments. In FIG. 7E, fourth layout cell 700E includes PO patterns and M0 regions for conductive line patterns at M0 layer, as indicated by the legends. In FIG. 7E, fourth layout cell 700E further includes VG pattern candidates at layout regions 701′ and 703′ adjacent to a lower side of fourth layout cell 700E; and VG pattern candidates at layout regions 702′ and 704′ adjacent to an upper side of fourth layout cell 700E. Therefore, each one of layout regions 701′ and 703′ is based on accommodating VG patterns adjacent to one side of the layout region, while each one of layout regions 702′ and 704′ is based on accommodating VG patterns adjacent to the other side of the layout region. In this example, VG pattern candidates adjacent to the cell boundary are permitted within area 728 that has a zig-zag pattern. In some embodiments, a complementary counterpart of the example in FIG. 7E is defined based on vertically flipping fourth layout cell 700E.

FIG. 7F is a layout diagram of a portion of a fifth layout cell example 700F based on the base layout cell 700A of FIG. 7A, in accordance with some embodiments. In FIG. 7F, fifth layout cell 700F includes PO patterns and M0 regions for conductive line patterns at M0 layer, as indicated by the legends. In FIG. 7F, fifth layout cell 700F further includes V0 pattern candidates at layout region 701 at both the upper portion and the bottom portion of layout region 701; and V0 pattern candidates at layout region 703 at both the upper portion and the bottom portion of layout region 703. Therefore, each one of layout regions 701 and 703 is based on accommodating V0 patterns adjacent to opposite sides of the layout region, while each one of layout regions 702 and 704 is based on prohibiting any V0 patterns adjacent to opposite sides of the layout region. In this example, V0 pattern candidates adjacent to the cell boundary are permitted within areas 732 and 736 in parallel with the direction of the PO patterns. In some embodiments, a complementary counterpart of the example in FIG. 7F is defined based on fifth layout cell 700F such that each one of layout regions 701 and 703 is based on prohibiting any V0 patterns adjacent to opposite sides of the layout region, while each one of layout regions 702 and 704 is based on accommodating V0 patterns adjacent to opposite sides of the layout region.

FIG. 7G is a layout diagram of a portion of a sixth layout cell example 700G based on the base layout cell 700A of FIG. 7A, in accordance with some embodiments. In FIG. 7G, sixth layout cell 700G includes PO patterns and M0 regions for conductive line patterns at M0 layer, as indicated by the legends. In FIG. 7G, sixth layout cell 700G further includes V0 pattern candidates at layout regions 703 and 705 adjacent to an upper side of sixth layout cell 700G; and V0 pattern candidates at layout regions 702 and 704 adjacent to a lower side of sixth layout cell 700G. Therefore, each one of layout regions 703 and 705 is based on accommodating V0 patterns adjacent to one side of the layout region, while each one of layout regions 702 and 704 is based on accommodating V0 patterns adjacent to the other side of the layout region. In this example, V0 pattern candidates adjacent to the cell boundary are permitted within area 738 that has a zig-zag pattern. In some embodiments, a complementary counterpart of the example in FIG. 7G is defined based on vertically flipping sixth layout cell 700G.

FIG. 7H is a layout diagram of a portion of a seventh layout cell example 700H based on the base layout cell 700A of FIG. 7A, in accordance with some embodiments. In FIG. 7H, seventh layout cell 700H includes PO patterns and M0 regions for conductive line patterns at M0 layer, as indicated by the legends. In FIG. 7H, the upper and lower M0 regions adjacent to the upper and lower cell boundaries are suitable for forming M0 conductive line patterns 742 in association with the corresponding V0 patterns in FIG. 7F. In some embodiments, a complementary counterpart of the example in FIG. 7H is defined based on the complementary counterpart of the example in FIG. 7F.

FIG. 7I is a layout diagram of a portion of an eighth layout cell example 700I based on the base layout cell 700A of FIG. 7A, in accordance with some embodiments. In FIG. 7I, eighth layout cell 700I includes PO patterns and M0 regions for conductive line patterns at M0 layer, as indicated by the legends. In FIG. 7I, the upper and lower M0 regions adjacent to the upper and lower cell boundaries are suitable for forming M0 conductive tract patterns 746 in association with the corresponding V0 patterns in FIG. 7G. In some embodiments, a complementary counterpart of the example in FIG. 7IH is defined based on the complementary counterpart of the example in FIG. 7G.

In some embodiments, various combinations of the constraints represented by the examples in FIGS. 7B-7I and the corresponding complementary counterpart examples are usable to form candidate layout cells for a set of placement sites with suitable placement site types of an edge placement site of the set of placement sites in a reversed first direction (e.g., the left-most edge placement site, corresponding to layout region 701 in FIGS. 7A-7I). In some embodiments and as non-limiting examples, a candidate layout cell for a set of placement sites with a left-most edge placement site being the first placement type illustrated in FIG. 6 includes a first combination of constraints based on the examples in FIGS. 7B, 7D, 7F, and 7H, a second combination of constraints based on the examples in FIGS. 7B, 7E, 7F, and 7H, a third combination of constraints based on complimentary counterpart examples of the examples in FIGS. 7C, 7D, 7G, and 7I, and a fourth combination of constraints based on complimentary counterpart examples of the examples in FIGS. 7C, 7E, 7G, and 7I. Also, in some embodiments and as non-limiting examples, a candidate layout cell for a set of placement sites with a left-most edge placement site being the second placement type illustrated in FIG. 6 includes a fifth combination of constraints based on complimentary counterpart examples of the examples in FIGS. 7B, 7D, 7F, and 7H, a sixth combination of constraints based on complimentary counterpart examples of the examples in FIGS. 7B, 7E, 7F, and 7H, a seventh combination of constraints based on the examples in FIGS. 7C, 7D, 7G, and 7I, and an eighth combination of constraints based on the examples in FIGS. 7C, 7E, 7G, and 7I.

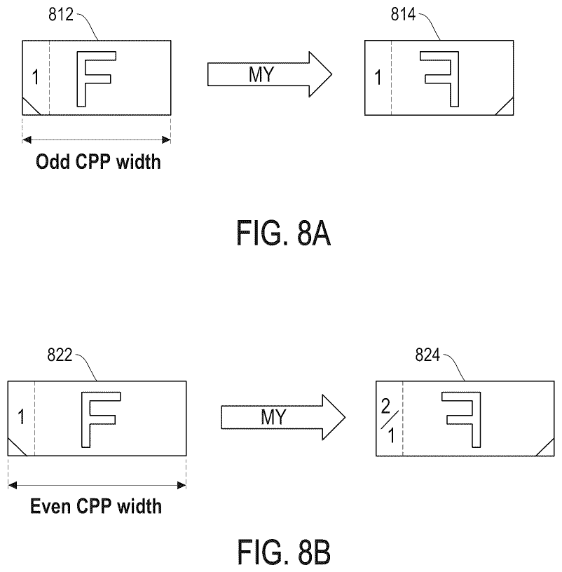

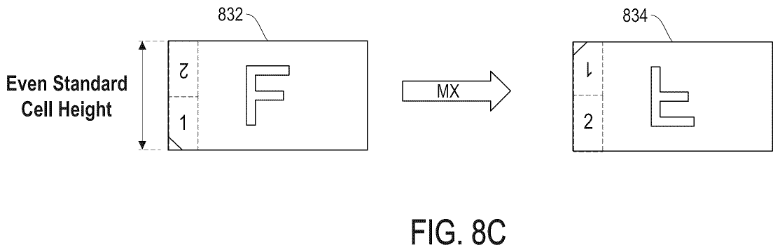

Moreover, not all flipped variations of a candidate layout cell are usable to meet the constraints and guidelines as illustrated in FIGS. 5A, 5B, and 6. In this regard, FIGS. 8A-8C are simplified layout diagrams of various flipped variations of a base candidate layout cell, in accordance with some embodiments. In FIGS. 8A-8C, the letter “F” and the triangle at the corners of the layout cells are used to indicate how the layout cells are flipped with respect to one another.

In FIG. 8A, a base candidate layout cell 812 has a cell width of an odd number of CPP (e.g., a cell width of 5 CPP) and is usable for a scenario where the left-most edge placement site is a certain placement type (e.g., the first placement type, labeled with numeral 1, in this example). In some embodiments, the horizontally flipped variation 814 (e.g., flipping with respect to an Y axis, indicated by the arrow with the label “MY”) of base candidate layout cell 812 is still usable for the scenario where the left-most edge placement site is that certain placement type, when there are VD patterns, V0 patterns, or M0 track patterns associated with V0 patterns adjacent to a lower side of the base candidate layout cell 812 and there are no VG patterns adjacent to the lower side of the base candidate layout cell 812. In some embodiments, the horizontally flipped variation 814 is not usable at all when there are VG patterns adjacent to the lower side of the base candidate layout cell 812. In some embodiments, there are no restrictions with respect to using the horizontally flipped variation 814 when there are no VD patterns, V0 patterns, M0 track patterns associated with V0 patterns, or VG patterns adjacent to the lower side of the base candidate layout cell 812.

In FIG. 8B, a base candidate layout cell 822 has a cell width of an even number of CPP (e.g., a cell width of 6 CPP) and is usable for a scenario where the left-most edge placement site is a certain placement type (e.g., the first placement type, labeled with numeral 1, in this example). In some embodiments, the horizontally flipped variation 824 of base candidate layout cell 822 is usable for the scenario where the left-most edge placement site is a different placement type (e.g., the second placement type, labeled with numeral 2, in this example), when there are VD patterns, V0 patterns, or M0 track patterns associated with V0 patterns adjacent to a lower side of the base candidate layout cell 822 and there are no VG patterns adjacent to the lower side of the base candidate layout cell 822. In some embodiments, the horizontally flipped variation 824 of base candidate layout cell 822 is still usable for the scenario where the left-most edge placement site is that certain placement type (e.g., the first placement type, labeled with numeral 1, in this example), when there are no VD patterns, V0 patterns, or M0 track patterns associated with V0 patterns adjacent to the lower side of the base candidate layout cell 822 and there are VG patterns adjacent to the lower side of the base candidate layout cell 822. In some embodiments, the horizontally flipped variation 824 is not usable at all when there are VD patterns, V0 patterns, or M0 track patterns associated with V0 patterns adjacent to the lower side of the base candidate layout cell 822, and there are VG patterns adjacent to the lower side of the base candidate layout cell 822. In some embodiments, there are no restrictions with respect to using the horizontally flipped variation 824 when there are no VD patterns, V0 patterns, M0 track patterns associated with V0 patterns, or VG patterns adjacent to the lower side of the base candidate layout cell 822.

In FIG. 8C, a base candidate layout cell 832 has a cell height of an even number of standard cell height (e.g., a cell height of 2H) and is usable for a scenario where the lower-left-most edge placement site is a certain placement type (e.g., the first placement type, labeled with numeral 1, in this example). As such, in this example with a cell height of 2H, the upper-left-most edge placement site would be a flipped version of a different placement type (e.g., the flipped second placement type, labeled with flipped numeral 2, in this example). In some embodiments, the vertically flipped variation 834 (e.g., flipping with respect to an X axis, indicated by the arrow with the label “MX”) of base candidate layout cell 832 is usable for the scenario where the lower-left-most edge placement site is the other placement type.

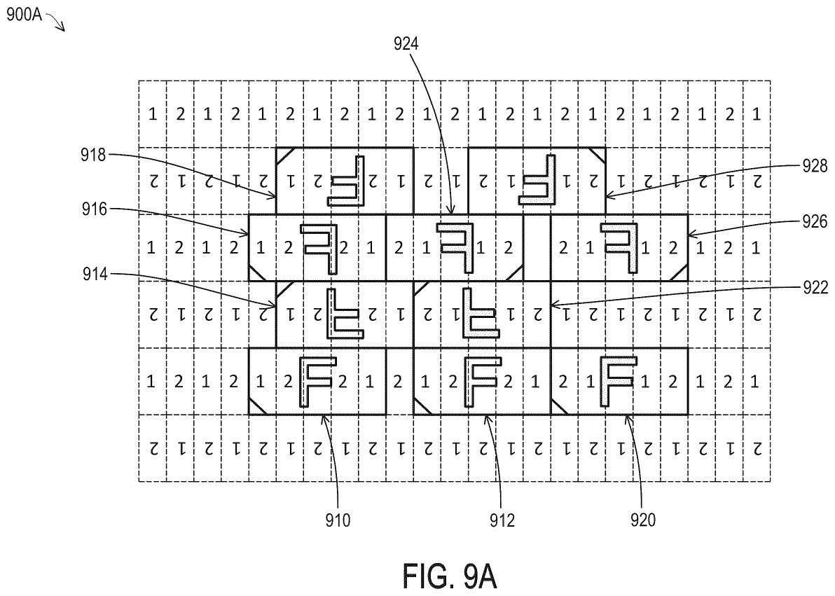

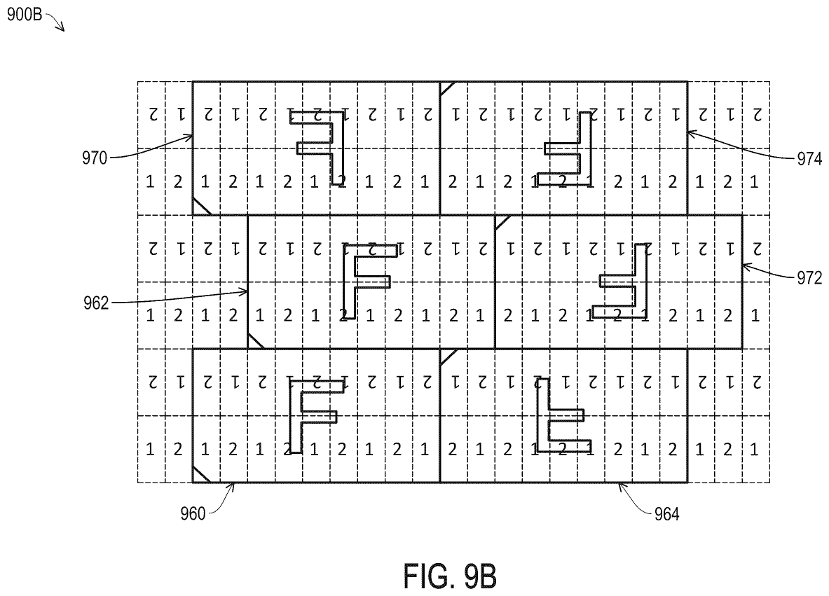

FIG. 9A is a simplified layout diagram of a portion of a layout plan example 900A, in accordance with some embodiments. In FIG. 9A, layout plan 900A includes a plurality of placement sites as similarly illustrated with reference to FIG. 6, where each rectangular box with a numeral 1, 2, vertically flipped 1, or vertically flipped 2 represents a placement site of different placement types. Various layout cells in FIG. 9A are used as non-limiting examples of how layout cells and their variations are placed with respect to placement cites in view of the examples in FIG. 8A-8C.

In FIG. 9A, a first base layout cell 910 is for a set of placement sets with the left-most edge placement site being a first placement type. In this example, first base layout cell 910 has a cell width of 5 CPP and a cell height of 1H. In some embodiments, a layout cell 912 based on first base layout cell 910 is also usable for a scenario where a left-most edge placement site is the first placement type. In some embodiments, a layout cell 914 based on vertical flipping first base layout cell 910 is usable for a scenario where a left-most edge placement site is a flipped first placement type. In some embodiments, a layout cell 916 based on horizontally flipping first base layout cell 910 is usable for a scenario where a left-most edge placement site is the first placement type. Also, in some embodiments, a layout cell 918 based on vertically flipping layout cell 916 is usable for a scenario where a left-most edge placement site is a flipped first placement type.

Moreover, in this example, a second base layout cell 920 is for a set of placement sets with the left-most edge placement site being a second placement type. In this example, second base layout cell 920 has a cell width of 5 CPP and a cell height of 1H. In some embodiments, a layout cell 922 based on vertical flipping second base layout cell 920 is usable for a scenario where a left-most edge placement site is a flipped second placement type. In some embodiments, layout cells 924 and 926 based on horizontally flipping second base layout cell 920 is usable for a scenario where a left-most edge placement site is a second placement type. Also, in some embodiments, a layout cell 928 based on vertically flipping layout cell 926 is usable for a scenario where a left-most edge placement site is a flipped second placement type.

In some embodiments, according to the example in FIG. 9A, the candidate layout cells for a circuit cell having a cell width of 5 CPP and a cell height of 1H include at least a first base layout cell 910 for the left-most edge placement site being a first placement type and a second base layout cell 920 for the left-most edge placement site being a second placement type. Meanwhile, the horizontally flipped first base layout cell (e.g., layout cell 916) is also usable for the left-most edge placement site being the first placement type; and the horizontally flipped second base layout cell (e.g., layout cell 926) is also usable for the left-most edge placement site being the second placement type. That is, in some embodiments, four variants of layout cells are prepared for a circuit cell (width: 5 CPP and height: 1H) to be used in conjunction with the placement sites in FIG. 6 to meet the constraints and guidelines illustrated in the examples in FIGS. 5A and 5B.

FIG. 9B is a simplified layout diagram of a portion of a layout plan example 900B, in accordance with some embodiments. In FIG. 9B, layout plan 900B includes a plurality of placement sites as similarly illustrated with reference to FIG. 6, where each rectangular box with a numeral 1, 2, vertically flipped 1, or vertically flipped 2 represents a placement site. Various layout cells in FIG. 9B are used as non-limiting examples of how layout cells and their variations are placed with respect to placement cites in view of the examples in FIG. 8A-8C.

In FIG. 9B, a base layout cell 960 is for a set of placement sets with the lower-left-most edge placement site being a first placement type. In this example, base layout cell 960 has a cell width of 9 CPP and a cell height of 2H. In some embodiments, a layout cell 962 based on base layout cell 960 is also usable for a scenario where a lower-left-most edge placement site is the first placement type and an upper-left-most edge placement site is a flipped second placement type. In some embodiments, a layout cell 964 based on vertical flipping base layout cell 960 is usable for a scenario where a lower-left-most edge placement site is a flipped second placement type. In some embodiments, a layout cell 976 based on horizontally flipping base layout cell 960 is usable for a scenario where a lower-left-most edge placement site is the first placement type. Also, in some embodiments, layout cells 972 and 974 based on vertically flipping layout cell 970 are usable for a scenario where a lower-left-most edge placement site is the second placement type.

In some embodiments, according to the example in FIG. 9B, the candidate layout cells for a circuit cell having a cell width of 9 CPP and a cell height of 2H include at least a base layout cell (e.g., layout cell 960) for the lower-left-most edge placement site being a first placement type and a vertically-flipped base layout cell (e.g., layout cell 964) for the lower-left-most edge placement site being a second placement type. That is, in some embodiments, two variants of layout cells are prepared for a circuit cell (width: 9 CPP and height: 2H) to be used in conjunction with the placement sites in FIG. 6 and the constraint examples in FIGS. 5A and 5B.

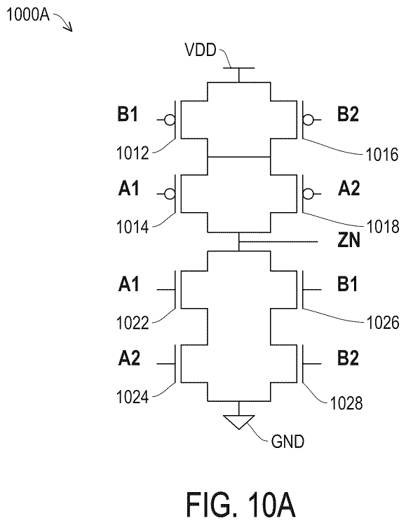

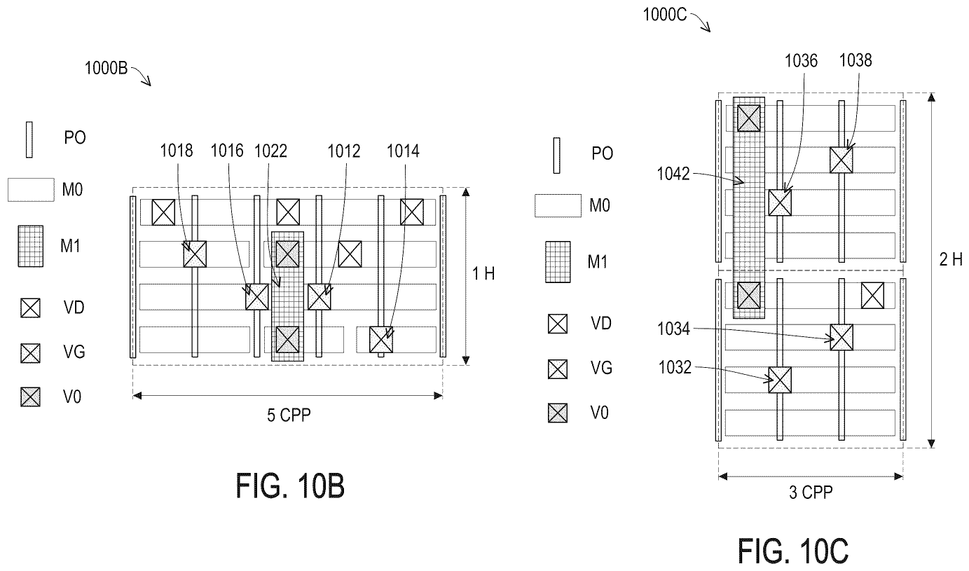

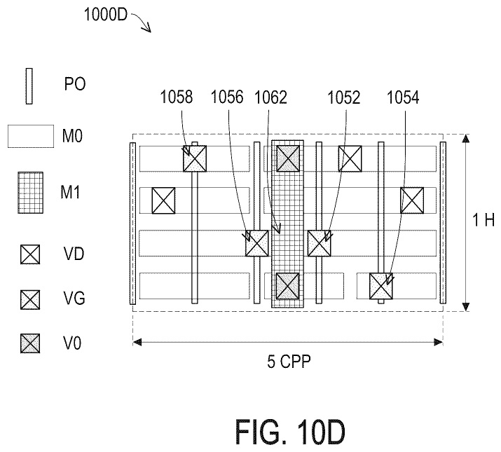

FIG. 10A is a circuit diagram of an AND-OR-INVERT (AOI) logic 1000A, in accordance with some embodiments. In FIG. 10A, AOI logic 1000A includes P-type transistors 1012, 1014, 1016, and 1018 and N-type transistors 1022, 1024, 1026, and 1028. In FIG. 10A, a first drain/source terminal of P-type transistor 1012 is electrically coupled to a first power supply (labeled VDD). A second drain/source terminal of P-type transistor 1012 is electrically coupled to a first drain/source terminal of P-type transistor 1014. A second drain/source terminal of P-type transistor 1014 is electrically coupled to an output terminal ZN of AOI logic 1000A. A first drain/source terminal of P-type transistor 1016 is electrically coupled to the first power supply. A second drain/source terminal of P-type transistor 1016 is electrically coupled to a first drain/source terminal of P-type transistor 1018 and the first drain/source terminal of P-type transistor 1014. A second drain/source terminal of P-type transistor 1018 is electrically coupled to the output terminal ZN.

Also, a first drain/source terminal of N-type transistor 1022 is electrically coupled to the output terminal ZN. A second drain/source terminal of N-type transistor 1022 is electrically coupled to a first drain/source terminal of N-type transistor 1024. A second drain/source terminal of N-type transistor 1024 is electrically coupled to a second power supply (labeled GND). A first drain/source terminal of N-type transistor 1026 is electrically coupled to the output terminal ZN. A second drain/source terminal of N-type transistor 1026 is electrically coupled to a first drain/source terminal of N-type transistor 1028. A second drain/source terminal of N-type transistor 1028 is electrically coupled to the second power supply.

In FIG. 10A, the gate terminals of P-type transistor 1014 and N-type transistor 1022 are electrically coupled to an input terminal A1 of AOI logic 1000A. The gate terminals of P-type transistor 1018 and N-type transistor 1024 are electrically coupled to an input terminal A2 of AOI logic 1000A. The gate terminals of P-type transistor 1012 and N-type transistor 1026 are electrically coupled to an input terminal B1 of AOI logic 1000A. The gate terminals of P-type transistor 1016 and N-type transistor 1028 are electrically coupled to an input terminal B2 of AOI logic 1000A. Accordingly, AOI logic 1000A is configured to perform a logic operation based on an expression of ZN=/(A1A2+B1B2).

FIGS. 10B-10D are layout diagrams of candidate layout cells of AOI logic 1000A in FIG. 10A, in accordance with some embodiments. FIGS. 10B-10D include legends of various types of layout patterns used therein, which are the same as the legends presented in FIG. 4A, and detailed description thereof is thus omitted. In some embodiments, the candidate layout cells in FIGS. 10B-10D meet constraints based on various combinations of the examples in FIG. 7B-7E. In some embodiments, a plurality of candidate layout cells for AOI logic 1000A is usable for having a left-most (or lower-left-most) edge placement site being the first placement type or the second placement type as illustrated in the example in FIG. 6 in view of the examples in FIGS. 7A-9B.

In FIG. 10B, layout cell 1000B has a cell width of 5 CPP and a cell height of 1H. Layout cell 1000B is consistent with a combination of the constraints based on the examples of FIGS. 7B and 7D. Layout cell 1000B is also consistent with a combination of the constraints based on the examples of FIGS. 7B and 7E. In this example, layout cell 1000B includes VG patterns 1012, 1014, 1016, and 1018 corresponding to input terminals A1, A2, B1, and B2 in FIG. 10A. In this example, layout cell 1000B further includes an M1 conductive line pattern 1022 corresponding to output terminal ZN in FIG. 10A.

In FIG. 10C, layout cell 1000B has a cell width of 3 CPP and a cell height of 2H. Layout cell 1000C is consistent with a combination of the constraints based on the examples of FIGS. 7C and 7D. In this example, layout cell 1000C includes VG patterns 1032, 1034, 1036, and 1038 corresponding to input terminals A1, A2, B1, and B2 in FIG. 10A. In this example, layout cell 1000C further includes an M1 conductive line pattern 1042 corresponding to output terminal ZN in FIG. 10A.

In FIG. 10D, layout cell 1000D has a cell width of 5 CPP and a cell height of 1H. Layout cell 1000D is consistent with a combination of the constraints based on the examples of FIGS. 7C and 7E. In this example, layout cell 1000D includes VG patterns 1052, 1054, 1056, and 1058 corresponding to input terminals A1, A2, B1, and B2 in FIG. 10A. In this example, layout cell 1000D further includes an M1 conductive line pattern 1062 corresponding to output terminal ZN in FIG. 10A.

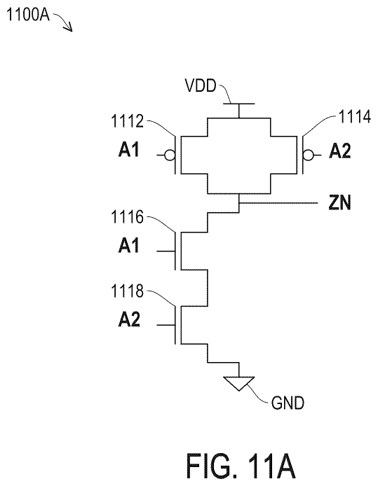

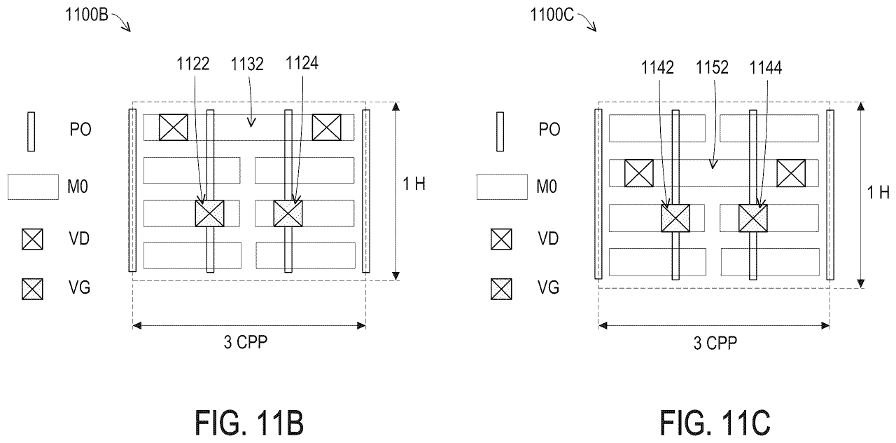

FIG. 11A is a circuit diagram of a NAND logic 1100A, in accordance with some embodiments. In FIG. 11A, NAND logic 1100A includes P-type transistors 1112 and 1114 and N-type transistors 1116 and 1118. In FIG. 11A, a first drain/source terminal of P-type transistor 1112 and a first drain/source terminal of P-type transistor 1114 are electrically coupled to a first power supply (labeled VDD). A second drain/source terminal of P-type transistor 1112 and a second drain/source terminal of P-type transistor 1114 are electrically coupled to an output terminal ZN of NAND logic 1100A. A first drain/source terminal of N-type transistor 1116 is electrically coupled to the output terminal ZN. A second drain/source terminal of N-type transistor 1116 is electrically coupled to a first drain/source terminal of N-type transistor 1118. A second drain/source terminal of N-type transistor 1118 is electrically coupled to a second power supply (labeled GND).

In FIG. 11A, the gate terminals of P-type transistor 1112 and N-type transistor 1116 are electrically coupled to an input terminal A1 of NAND logic 1100A. The gate terminals of P-type transistor 1114 and N-type transistor 1118 are electrically coupled to an input terminal A2 of NAND logic 1100A. Accordingly, NAND logic 1100A is configured to perform a logic operation based on an expression of ZN=/A1A2.

FIGS. 11B-11C are layout diagrams of candidate layout cells of NAND logic 1100A in FIG. 11A, in accordance with some embodiments. FIGS. 11B-11C include legends of various types of layout patterns used therein, which are the same as the legends presented in FIG. 4A, and detailed description thereof is thus omitted. In some embodiments, the candidate layout cells in FIGS. 11B-11C meet constraints based on various combinations of the examples in FIG. 7B-7E. In some embodiments, a plurality of candidate layout cells for NAND logic 1100A is usable for having a left-most edge placement site being the first placement type or the second placement type as illustrated in the example in FIG. 6 in view of the examples in FIGS. 7A-9B.

In FIG. 11B, layout cell 1100B has a cell width of 3 CPP and a cell height of 1H. Layout cell 1100B is consistent with a combination of the constraints based on the examples of FIGS. 7B and 7D, a combination of the constraints based on the examples of FIGS. 7B and 7E, or a combination of the constraints based on the examples of FIGS. 7C and 7D. In this example, layout cell 1100B includes VG patterns 1122 and 1124 corresponding to input terminals A1 and A2 in FIG. 11A. In this example, layout cell 1100B further includes an M0 conductive line pattern 1132 corresponding to output terminal ZN in FIG. 11A.

In FIG. 11C, layout cell 1100C has a cell width of 3 CPP and a cell height of 1H. Layout cell 1100C is consistent with a combination of the constraints based on the examples of FIGS. 7C and 7E. In this example, layout cell 1100C includes VG patterns 1142 and 1144 corresponding to input terminals A1 and A2 in FIG. 11A. In this example, layout cell 1100C further includes an M0 conductive line pattern 1152 corresponding to output terminal ZN in FIG. 11A.

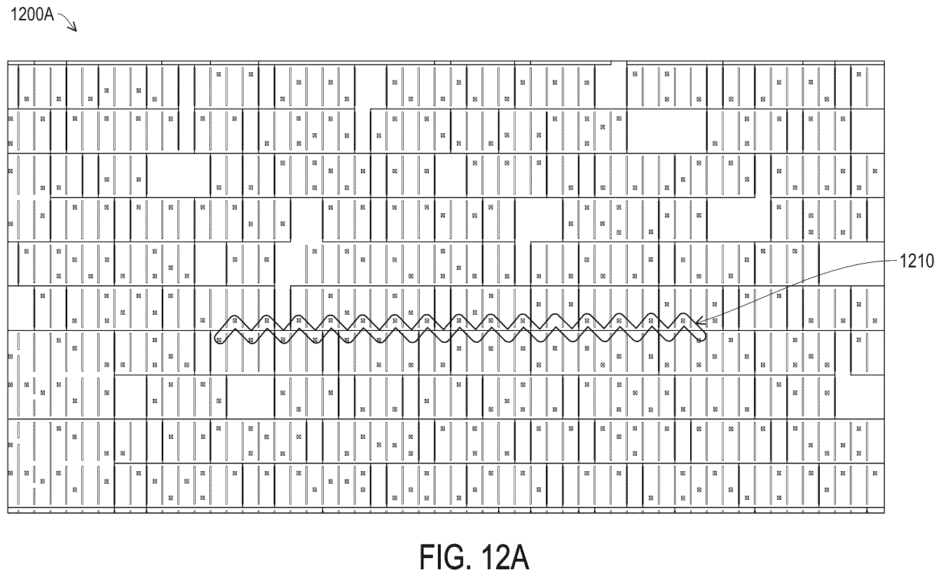

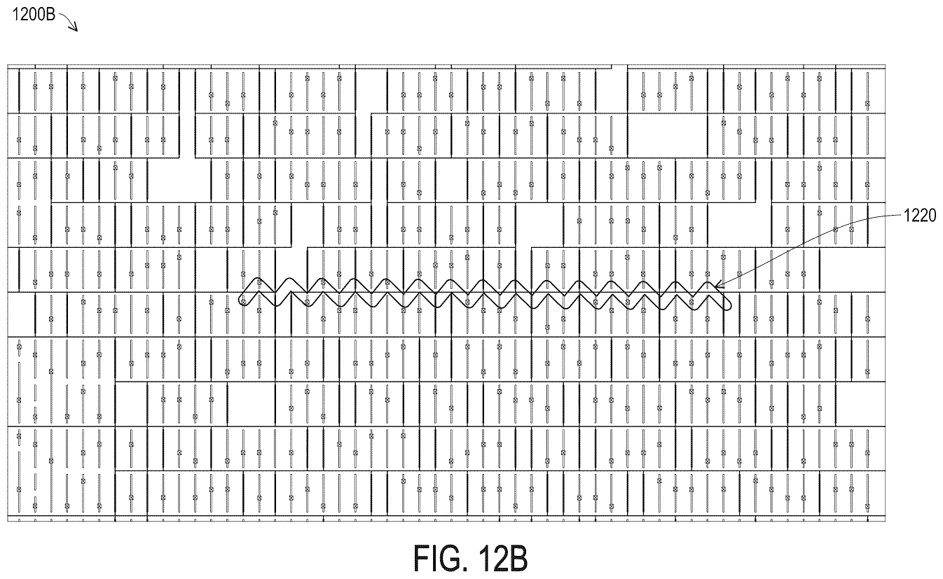

FIG. 12A is a diagram of a simplified layout plan example 1200A, in accordance with some embodiments. In FIG. 12A, layout plan example 1200A includes a plurality of layout cells, which include gate patterns and corresponding VD patterns (not labeled). In FIG. 12A, based on the placement sites and the constraints in the examples of FIG. 6 and in view of the implementation examples in FIGS. 7A-11C, VD patterns adjacent to a cell boundary are arranged within an area 1210 having a zig-zag shape along the cell boundary meeting the constraints and guidelines as illustrated in FIG. 5A.

FIG. 12B is a diagram of a simplified layout plan example 1200B, in accordance with some embodiments. In FIG. 12B, layout plan example 1200B includes a plurality of layout cells, which include gate patterns and corresponding VG patterns (not labeled). In FIG. 12B, based on the placement sites and the constraints in the examples of FIG. 6 and in view of the implementation examples in FIGS. 7A-11C, VG patterns adjacent to a cell boundary are arranged within an area 1220 having a zig-zag shape along the cell boundary meeting the constraints and guidelines as illustrated in FIG. 5A.

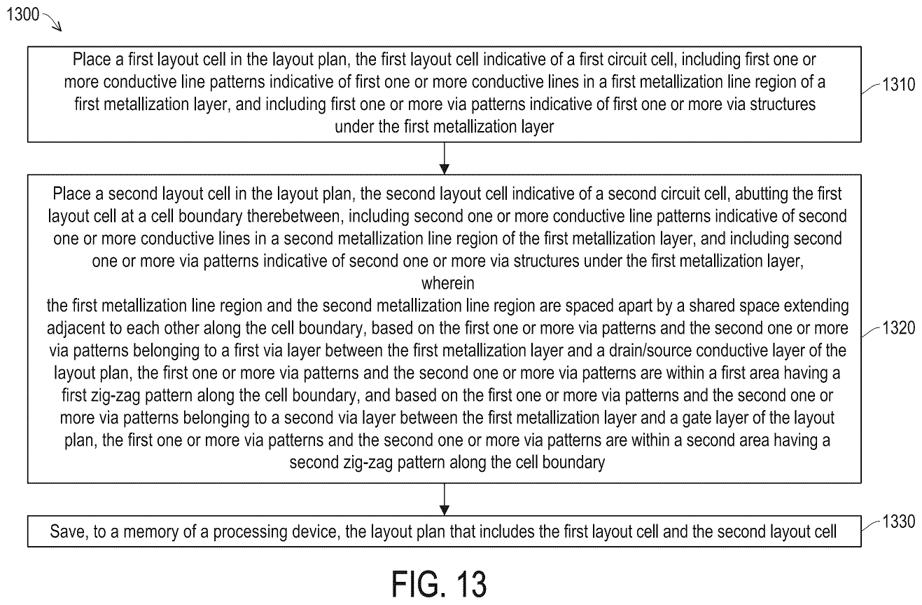

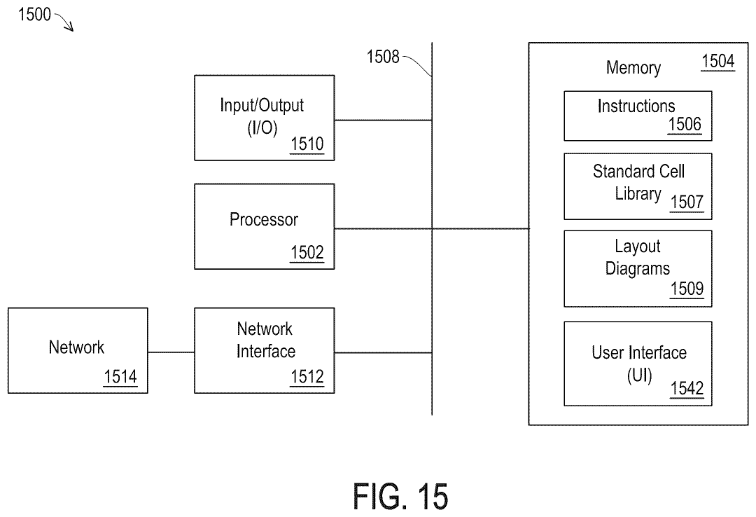

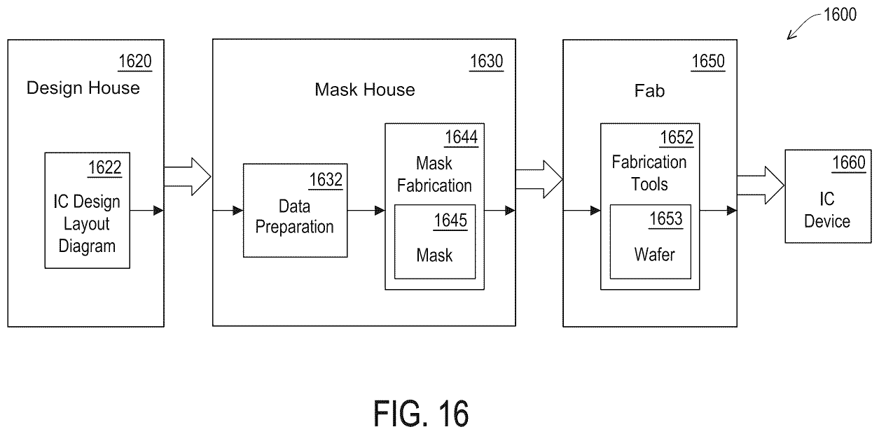

FIG. 13 is a flowchart of a method 1300 of generating a layout plan for a semiconductor device, in accordance with some embodiments. In some embodiments, various operations of method 1300 correspond to various combinations of the examples in FIGS. 6-12B in order to meet the constraints or guidelines based on zig-zag patterns for various features as illustrated in FIGS. 5A and 5B. In some embodiments, method 1300 corresponds to one or more operations performed based on, in whole or in part, an EDA system 1500 as illustrated in FIG. 15 and/or an integrated circuit (IC) manufacturing system 1600 as illustrated in FIG. 16. As in FIG. 13, method 1300 includes blocks 1310-1330.

At block 1310, a first layout cell (e.g., layout cell 510 or layout cell 520 in FIGS. 5A-5B) is placed in the layout plan (e.g., layout plan 500). In some embodiments, the first layout cell is indicative of a first circuit cell, includes first one or more conductive line patterns indicative of first one or more conductive lines in a first metallization line region of a first metallization layer (e.g., M0 patterns for the M0 layer), and includes first one or more via patterns indicative of first one or more via structures under the first metallization layer (e.g., VD patterns for the VD layer or VG patterns for the VG layer).

At block 1320, a second layout cell (e.g., layout cell 520 or layout cell 530 in FIGS. 5A-5B) is placed in the layout plan (e.g., layout plan 500). In some embodiments, the second layout cell is indicative of a second circuit cell, and abuts the first layout cell at a cell boundary therebetween. In some embodiments, the second layout cell includes second one or more conductive line patterns indicative of second one or more conductive lines in a second metallization line region of the first metallization layer (e.g., M0 patterns for the M0 layer), and includes second one or more via patterns indicative of second one or more via structures under the first metallization layer (e.g., VD patterns for the VD layer or VG patterns for the VG layer). In some embodiments, the first metallization line region and the second metallization line region are spaced apart by a shared space extending along the cell boundary.

In some embodiments, based on the first one or more via patterns and the second one or more via patterns belonging to a first via layer between the first metallization layer and a drain/source conductive layer of the layout plan (e.g., VD patterns for the VD layer), the first one or more via patterns and the second one or more via patterns are within a first area (e.g., first area 542 in FIG. 5A) has a first zig-zag pattern along the cell boundary. In some embodiments, based on the first one or more via patterns and the second one or more via patterns belonging to a second via layer between the first metallization layer and a gate layer of the layout plan (e.g., VG patterns for the VG layer), the first one or more via patterns and the second one or more via patterns are within a second area having a second zig-zag pattern along the cell boundary (e.g., second area 546 in FIG. 5A).

At block 1330, the layout plan that includes the first layout cell and the second layout cell is saved to a memory of a processing device (e.g., EDA system 1500 in FIG. 15).

In some embodiments, the cell boundary extends along a first direction, and the first metallization line region and the second metallization line region are disposed based on a metallization pitch (e.g., M0 pitch in FIG. 5A) along a second direction different from the first direction. In some embodiments, based on the first one or more via patterns and the second one or more via patterns belonging to a first via layer between the first metallization layer and a drain/source conductive layer of the layout plan (e.g., VD patterns for the VD layer), the first one or more via patterns and the second one or more via patterns are disposed based on a first minimum via pitch (e.g., VD Pitch′ in FIG. 5A) that is greater than the metallization pitch. In some embodiments, based on the first one or more via patterns and the second one or more via patterns belonging to a second via layer between the first metallization layer and the gate layer of the layout plan (e.g., VG patterns for the VG layer), the first one or more via patterns and the second one or more via patterns are disposed based on a second minimum via pitch (e.g., VG Pitch′ in FIG. 5A) that is greater than the metallization pitch.

In some embodiments, one or more gate patterns (e.g., PO patterns in FIG. 5A) in the gate layer of the layout plan are disposed based on a gate pitch (e.g., 1 CPP in FIG. 5A) along the first direction. In some embodiments, the first minimum via pitch (e.g., VD Pitch′ in FIG. 5A) is one of at least two times the metallization pitch or at least the gate pitch. In some embodiments, the second minimum via pitch (e.g., VG Pitch′ in FIG. 5A) is one of at least two times the metallization pitch or at least the gate pitch.

In some embodiments, the first layout cell further includes third one or more via patterns (e.g., V0 patterns of layout cell 520 in FIG. 5A) belonging to a third via layer between the first metallization line region and a third metallization line region of a second metallization layer (e.g., M1 layer) above the first metallization layer (e.g., M0 layer); and the second layout cell further comprises fourth one or more via patterns (e.g., V0 patterns of layout cell 530 in FIG. 5A) belonging to the third via layer. In some embodiments, the third one or more via patterns are spaced apart from the fourth one or more via patterns based on at least a third minimum via pitch (e.g., V0 pitch′ in FIG. 5A) that is greater than the metallization pitch. In some embodiments, the third minimum via pitch is one of at least two times the metallization pitch or at least the gate pitch.

In some embodiments, the first layout cell further includes a third conductive line pattern (e.g., a M1 pattern of cell 520 in FIG. 5A) of the second metallization layer (e.g., M1 layer), the second layout cell further comprises a fourth conductive line pattern (e.g., a M1 pattern of cell 530 in FIG. 5A) of the second metallization layer, and the third conductive line pattern and the fourth conductive line pattern are aligned along a second direction. In some embodiments, the third conductive line pattern and the fourth conductive line pattern are disposed based on a minimum end-to-end distance (e.g., M1 EtE′ in FIG. 5A) that is along the second direction and is greater than the metallization pitch.

In some embodiments, the first layout cell and the second layout cell include portions of a CMD pattern (e.g., CMD pattern 552 in FIG. 5B) for defining first one or more drain/source conductive structures of the first circuit cell and second one or more drain/source conductive structures of the second circuit cell. In some embodiments, the CMD pattern has a third zig-zag pattern along the cell boundary. In some embodiments, the first layout cell and the second layout cell include portions of a CPO pattern (e.g., CPO pattern 556 in FIG. 5B) for defining first one or more gate structures of the first circuit cell and second one or more gate structures of the second circuit cell. In some embodiments, the CPO pattern has a fourth zig-zag pattern along the cell boundary.

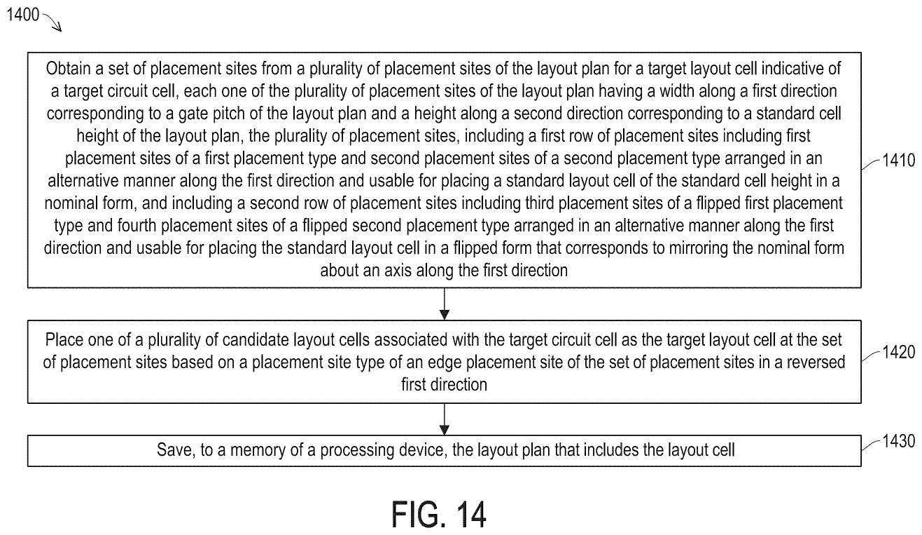

FIG. 14 is a flowchart of a method 1400 of generating a layout plan for a semiconductor device, in accordance with some embodiments. In some embodiments, various operations of method 1400 correspond to various combinations of the examples in FIGS. 6-12B in order to meet the constraints or guidelines based on zig-zag patterns for various features as illustrated in FIGS. 5A and 5B. In some embodiments, method 1400 corresponds to one or more operations performed based on, in whole or in part, an EDA system 1500 as illustrated in FIG. 15 and/or an integrated circuit (IC) manufacturing system 1600 as illustrated in FIG. 16. As in FIG. 14, method 1400 includes blocks 1410-1430.

At block 1410, a set of placement sites (e.g., the set of placement sites 630 in FIG. 6) is obtained from a plurality of placement sites (e.g., the plurality of placement sites 600 in FIG. 6) of the layout plan for a target layout cell indicative of a target circuit cell. In some embodiments, each one of the plurality of placement sites of the layout plan having a width along a first direction corresponding to a gate pitch (e.g., 1 CPP in FIG. 6) of the layout plan and a height along a second direction corresponding to a standard cell height (e.g., 1H in FIG. 6) of the layout plan. In some embodiments, the plurality of placement sites includes a first row of placement sites (e.g., row 612, 614, or 616) including first placement sites of a first placement type and second placement sites of a second placement type arranged in an alternative manner along the first direction and usable for placing a standard layout cell of the standard cell height in a nominal form. In some embodiments, the plurality of placement sites includes including a second row of placement sites (e.g., row 615 or 617) including third placement sites of a flipped first placement type and fourth placement sites of a flipped second placement type arranged in an alternative manner along the first direction and usable for placing the standard layout cell in a flipped form that corresponds to mirroring the nominal form about an axis along the first direction. In some embodiments, the target layout cell has a cell height of the standard cell height, or the target layout cell has the cell height of two times the standard cell height.

In some embodiments, as illustrated based on the examples in FIGS. 5A and 5B, a shared space being defined along a boundary between the first row and the second row, where the shared space is free of any layout patterns in a first metallization layer of the layout plan. In some embodiments, as shown in the non-limiting example in FIG. 6, the first placement sites of the first row of placement sites abuts the fourth placement sites of the second row of placement sites. In some embodiments, as shown in the non-limiting example in FIG. 6, the second placement sites of the first row of placement sites abuts the third type placement sites of the second row of placement sites. In some embodiments, the first placement type indicates accommodating a via pattern under the first metallization layer of the layout plan disposed adjacent to a reversed second direction side of a corresponding placement site. In some embodiments, the second placement type indicates prohibiting any via pattern under the first metallization layer of the layout plan disposed adjacent to the reversed second direction side of the corresponding placement site.

At block 1420, one of a plurality of candidate layout cells associated with the target circuit cell is placed as the target layout cell at the set of placement sites based on a placement site type of an edge placement site of the set of placement sites in a reversed first direction (e.g., the left-most edge placement site), as described in the non-limiting example in FIG. 6 with candidate layout cells prepared in view of the examples in FIGS. 7A-11C.

In some embodiments, the plurality of candidate layout cells associated with the target circuit cell includes a candidate layout cell including first one or more layout regions and second one or more layout regions arranged in an alternative manner along the first direction, and each one of the first one or more layout regions and the second one or more layout regions corresponding to a respective placement site.

In some embodiments, each one of the first one or more layout regions is based on accommodating via patterns under the first metallization layer of the layout plan placed adjacent to opposite sides of the candidate layout cell with respect to the second direction, and each one of the second one or more layout regions is based on prohibiting any via patterns under the first metallization layer of the layout plan placed adjacent to opposite sides of the candidate layout cell with respect to the second direction.

In some embodiments, each one of the first one or more layout regions is based on accommodating a first via pattern under the first metallization layer of the layout plan placed adjacent to a first side of the candidate layout cell and prohibiting any via patterns under the first metallization layer of the layout plan placed adjacent to a second side of the candidate layout cell. In some embodiments, each one of the second one or more layout regions is based on accommodating a second via pattern under the first metallization layer of the layout plan placed adjacent to the second side of the candidate layout cell and prohibiting any via patterns under the first metallization layer of the layout plan placed adjacent to the first side of the candidate layout cell. In some embodiments, the first side of the candidate layout cell and the second side of the candidate layout cell are opposite sides with respect to the second direction.

In some embodiments, the via patterns are between the first metallization layer and first one or more drain/source conductive layer of the layout plan (e.g., VD patterns in FIG. 5A). in some embodiments, the via patterns are between the first metallization layer and first one or more gate layer of the layout plan (e.g., VG patterns in FIG. 5A)

At block 1430, the layout plan that includes the layout cell is saved to a memory of a processing device (e.g., EDA system 1500 in FIG. 15).

FIG. 15 is a block diagram of an EDA system 1500, in accordance with some embodiments. In some embodiments, EDA system 1500 includes an automatic placement and routing (APR) system. Methods described herein regarding placement of layout cells are implementable, for example, using EDA system 1500, in accordance with some embodiments.

In some embodiments, EDA system 1500 is a general purpose computing device including a hardware processor 1502 and a memory 1504 that includes a non-transitory, computer-readable storage medium. Memory 1504, amongst other things, is encoded with, i.e., stores, computer program code 1506, i.e., a set of executable instructions. Execution of instructions 1506 by hardware processor 1502 represents (at least in part) an EDA tool which implements a portion or all of the methods described herein in accordance with one or more embodiments (hereinafter, the noted processes and/or methods).

Processor 1502 is electrically coupled to memory 1504 via a bus 1508. Processor 1502 is also electrically coupled to an I/O interface 1510 by bus 1508. A network interface 1512 is also electrically connected to processor 1502 via bus 1508. Network interface 1512 is connected to a network 1514, so that processor 1502 and memory 1504 are capable of connecting to external elements via network 1514. Processor 1502 is configured to execute computer program code 1506 encoded in memory 1504 in order to cause system 1500 to be usable for performing a portion or all of the noted processes and/or methods. In one or more embodiments, processor 1502 is a central processing unit (CPU), a multi-processor, a distributed processing system, an application specific integrated circuit (ASIC), and/or a suitable processing unit.

In one or more embodiments, memory 1504 is an electronic, magnetic, optical, electromagnetic, infrared, and/or a semiconductor system (or apparatus or device). For example, memory 1504 includes a semiconductor or solid-state memory, a magnetic tape, a removable computer diskette, a random access memory (RAM), a read-only memory (ROM), a rigid magnetic disk, and/or an optical disk. In one or more embodiments using optical disks, memory 1504 includes a compact disk-read only memory (CD-ROM), a compact disk-read/write (CD-R/W), and/or a digital video disc (DVD).

In one or more embodiments, memory 1504 stores computer program code 1506 configured to cause system 1500 (where such execution represents (at least in part) the EDA tool) to be usable for performing a portion or all of the noted processes and/or methods. In one or more embodiments, memory 1504 also stores information which facilitates performing a portion or all of the noted processes and/or methods. In one or more embodiments, memory 1504 stores standard cell library 1507 of standard cells including such standard cells as disclosed herein. In one or more embodiments, memory 1504 stores one or more layout diagrams 1509 corresponding to one or more layouts disclosed herein.

EDA system 1500 includes I/O interface 1510. I/O interface 1510 is coupled to external circuitry. In one or more embodiments, I/O interface 1510 includes a keyboard, keypad, mouse, trackball, trackpad, touchscreen, and/or cursor direction keys for communicating information and commands to processor 1502.

EDA system 1500 also includes network interface 1512 coupled to processor 1502. Network interface 1512 allows system 1500 to communicate with network 1514, to which one or more other computer systems are connected. Network interface 1512 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1500.

System 1500 is configured to receive information through I/O interface 1510. The information received through I/O interface 1510 includes one or more of instructions, data, design rules, libraries of standard cells, and/or other parameters for processing by processor 1502. The information is transferred to processor 1502 via bus 1508. EDA system 1500 is configured to receive information related to a UI through I/O interface 1510. The information is stored in memory 1504 as user interface (UI) 1542.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1500. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 16 is a block diagram of an integrated circuit (IC) manufacturing system 1600, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1600.

In FIG. 16, IC manufacturing system 1600 includes entities, such as a design house 1620, a mask house 1630, and an IC manufacturer/fabricator (fab) 1650, that interact with one another in the design, development, and manufacturing cycles and/or services related to manufacturing an IC device 1660. The entities in system 1600 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1620, mask house 1630, and IC fab 1650 is owned by a single larger company. In some embodiments, two or more of design house 1620, mask house 1630, and IC fab 1650 coexist in a common facility and use common resources.

Design house (or design team) 1620 generates an IC design layout diagram 1622. IC design layout diagram 1622 includes various geometrical patterns designed for an IC device 1660. The geometrical patterns correspond to patterns of metal, oxide, or semiconductor layers that make up the various components of IC device 1660 to be fabricated. The various layers combine to form various IC features. For example, a portion of IC design layout diagram 1622 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1620 implements a proper design procedure to form IC design layout diagram 1622. The design procedure includes one or more of logic design, physical design or place and route. IC design layout diagram 1622 is presented in one or more data files having information of the geometrical patterns. For example, IC design layout diagram 1622 can be expressed in a GDSII file format or DFII file format.

Mask house 1630 includes data preparation 1632 and mask fabrication 1644. Mask house 1630 uses IC design layout diagram 1622 to manufacture one or more masks 1645 to be used for fabricating the various layers of IC device 1660 according to IC design layout diagram 1622. Mask house 1630 performs mask data preparation 1632, where IC design layout diagram 1622 is translated into a representative data file (RDF). Mask data preparation 1632 provides the RDF to mask fabrication 1644. Mask fabrication 1644 includes a mask writer. A mask writer converts the RDF to an image on a substrate, such as a mask (reticle) 1645 or a semiconductor wafer 1653. The design layout diagram 1622 is manipulated by mask data preparation 1632 to comply with particular characteristics of the mask writer and/or requirements of IC fab 1650. In FIG. 16, mask data preparation 1632 and mask fabrication 1644 are illustrated as separate elements. In some embodiments, mask data preparation 1632 and mask fabrication 1644 can be collectively referred to as mask data preparation.

In some embodiments, mask data preparation 1632 includes optical proximity correction (OPC) which uses lithography enhancement techniques to compensate for image errors, such as those that can arise from diffraction, interference, other process effects and the like. OPC adjusts IC design layout diagram 1622. In some embodiments, mask data preparation 1632 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1632 includes a mask rule checker (MRC) that checks the IC design layout diagram 1622 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1622 to compensate for photolithographic implementation effects during mask fabrication 1644, which may undo part of the modifications performed by OPC in order to meet mask creation rules.

In some embodiments, mask data preparation 1632 includes lithography process checking (LPC) that simulates processing that will be implemented by IC fab 1650 to fabricate IC device 1660. LPC simulates this processing based on IC design layout diagram 1622 to create a simulated manufactured device, such as IC device 1660. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1622.

It should be understood that the above description of mask data preparation 1632 has been simplified for the purposes of clarity. In some embodiments, data preparation 1632 includes additional features such as a logic operation (LOP) to modify the IC design layout diagram 1622 according to manufacturing rules. Additionally, the processes applied to IC design layout diagram 1622 during data preparation 1632 may be executed in a variety of different orders.

After mask data preparation 1632 and during mask fabrication 1644, a mask 1645 or a group of masks 1645 are fabricated based on the modified IC design layout diagram 1622. In some embodiments, mask fabrication 1644 includes performing one or more lithographic exposures based on IC design layout diagram 1622. In some embodiments, an electron-beam (e-beam) or a mechanism of multiple e-beams is used to form a pattern on a mask (photomask or reticle) 1645 based on the modified IC design layout diagram 1622. Mask 1645 can be formed in various technologies. In some embodiments, mask 1645 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1645 includes a transparent substrate (e.g., fused quartz) and an opaque material (e.g., chromium) coated in the opaque regions of the binary mask. In another example, mask 1645 is formed using a phase shift technology. In a phase shift mask (PSM) version of mask 1645, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1644 is used in a variety of processes. For example, such a mask(s) is used in an ion implantation process to form various doped regions in semiconductor wafer 1653, in an etching process to form various etching regions in semiconductor wafer 1653, and/or in other suitable processes.

IC fab 1650 is an IC fabrication business that includes one or more manufacturing facilities for the fabrication of a variety of different IC products. In some embodiments, IC Fab 1650 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1650 includes fabrication tools 1652 configured to execute various manufacturing operations on semiconductor wafer 1653 such that IC device 1660 is fabricated in accordance with the mask(s), e.g., mask 1645. In various embodiments, fabrication tools 1652 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1650 uses mask(s) 1645 fabricated by mask house 1630 to fabricate IC device 1660. Thus, IC fab 1650 at least indirectly uses IC design layout diagram 1622 to fabricate IC device 1660. In some embodiments, semiconductor wafer 1653 is fabricated by IC fab 1650 using mask(s) 1645 to form IC device 1660. In some embodiments, the IC fabrication includes performing one or more lithographic exposures based at least indirectly on IC design layout diagram 1622. Semiconductor wafer 1653 includes a silicon substrate or other proper substrate having material layers formed thereon. Semiconductor wafer 1653 further includes one or more of various doped regions, dielectric features, multilevel interconnects, and the like (formed at subsequent manufacturing steps).

In some aspects, a semiconductor device includes a first circuit cell including first one or more conductive lines in a first metallization line region of a first metallization layer and including first one or more via structures under the first metallization layer. The semiconductor device further includes a second circuit cell abutting the first circuit cell at a cell boundary therebetween, the second circuit cell including second one or more conductive lines in a second metallization line region of the first metallization layer and including second one or more via structures under the first metallization layer. The first metallization line region and the second metallization line region are spaced apart by a shared space extending along the cell boundary. Based on the first one or more via structures being between the first metallization layer and first one or more drain/source conductive structures of the first circuit cell and the second one or more via structures being between the first metallization layer and second one or more drain/source conductive structures of the second circuit cell, the first one or more via structures and the second one or more via structures are within a first area having a first zig-zag pattern along the cell boundary. Based on the first one or more via structures being between the first metallization layer and first one or more gate structures of the first circuit cell and the second one or more via structures being between the first metallization layer and second one or more gate structures of the second circuit cell, the first one or more via structures and the second one or more via structures are within a second area having a second zig-zag pattern along the cell boundary.

In some aspects, a method of generating a layout plan for a semiconductor device, includes placing a first layout cell in the layout plan and placing a second layout cell in the layout plan. The first layout cell is indicative of a first circuit cell, includes first one or more conductive line patterns indicative of first one or more conductive lines in a first metallization line region of a first metallization layer, and includes first one or more via patterns indicative of first one or more via structures under the first metallization layer. The second layout cell is indicative of a second circuit cell, abuts the first layout cell at a cell boundary therebetween, includes second one or more conductive line patterns indicative of second one or more conductive lines in a second metallization line region of the first metallization layer, and includes second one or more via patterns indicative of second one or more via structures under the first metallization layer. The method further includes saving, to a memory of a processing device, the layout plan that includes the first layout cell and the second layout cell. The first metallization line region and the second metallization line region are spaced apart by a shared space extending along the cell boundary. Based on the first one or more via patterns and the second one or more via patterns belonging to a first via layer between the first metallization layer and a drain/source conductive layer of the layout plan, the first one or more via patterns and the second one or more via patterns are within a first area having a first zig-zag pattern along the cell boundary. Based on the first one or more via patterns and the second one or more via patterns belonging to a second via layer between the first metallization layer and a gate layer of the layout plan, the first one or more via patterns and the second one or more via patterns are within a second area having a second zig-zag pattern along the cell boundary.

In some aspects, a method of generating a layout plan for a semiconductor device, includes obtaining a set of placement sites from a plurality of placement sites of the layout plan for a target layout cell indicative of a target circuit cell. Each one of the plurality of placement sites of the layout plan has a width along a first direction corresponding to a gate pitch of the layout plan and a height along a second direction corresponding to a standard cell height of the layout plan. The plurality of placement sites includes a first row of placement sites including first placement sites of a first placement type and second placement sites of a second placement type arranged in an alternative manner along the first direction and usable for placing a standard layout cell of the standard cell height in a nominal form. The plurality of placement sites includes a second row of placement sites including third placement sites of a flipped first placement type and fourth placement sites of a flipped second placement type arranged in an alternative manner along the first direction and usable for placing the standard layout cell in a flipped form that corresponds to mirroring the nominal form about an axis along the first direction. A shared space is defined along a boundary between the first row and the second row, the shared space being free of any layout patterns in a first metallization layer of the layout plan. The first placement sites of the first row of placement sites abut the fourth placement sites of the second row of placement sites, and the second placement sites of the first row of placement sites abut the third type placement sites of the second row of placement sites. The first placement type indicates accommodating a via pattern under the first metallization layer of the layout plan disposed adjacent to a reversed second direction side of a corresponding placement site. The second placement type indicates prohibiting any via pattern under the first metallization layer of the layout plan disposed adjacent to the reversed second direction side of the corresponding placement site. The method includes placing one of a plurality of candidate layout cells associated with the target circuit cell as the target layout cell at the set of placement sites based on a placement site type of an edge placement site of the set of placement sites in a reversed first direction. The method further includes saving, to a memory of a processing device, the layout plan that includes the layout cell.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

1. A semiconductor device, comprising:
a first circuit cell including first one or more conductive lines in a first metallization line region of a first metallization layer and including first one or more via structures under the first metallization layer; and
a second circuit cell abutting the first circuit cell at a cell boundary therebetween, the second circuit cell including second one or more conductive lines in a second metallization line region of the first metallization layer and including second one or more via structures under the first metallization layer,
wherein
the first metallization line region and the second metallization line region are spaced apart by a shared space extending along the cell boundary,
based on the first one or more via structures being between the first metallization layer and first one or more drain/source conductive structures of the first circuit cell and the second one or more via structures being between the first metallization layer and second one or more drain/source conductive structures of the second circuit cell, the first one or more via structures and the second one or more via structures are within a first area having a first zig-zag pattern along the cell boundary, and
based on the first one or more via structures being between the first metallization layer and first one or more gate structures of the first circuit cell and the second one or more via structures being between the first metallization layer and second one or more gate structures of the second circuit cell, the first one or more via structures and the second one or more via structures are within a second area having a second zig-zag pattern along the cell boundary.

2. The semiconductor device of claim 1, wherein
the cell boundary extends along a first direction,
the first metallization line region and the second metallization line region are disposed based on a metallization pitch along a second direction different from the first direction,
based on the first one or more via structures being between the first metallization layer and the first one or more drain/source conductive structures of the first circuit cell and the second one or more via structures being between the first metallization layer and the second one or more drain/source conductive structures of the second circuit cell, the first one or more via structures and the second one or more via structures are disposed based on a first minimum via pitch that is greater than the metallization pitch, and
based on the first one or more via structures being between the first metallization layer and the first one or more gate structures of the first circuit cell and the second one or more via structures being between the first metallization layer and the second one or more gate structures of the second circuit cell, the first one or more via structures and the second one or more via structures are disposed based on a second minimum via pitch that is greater than the metallization pitch.

3. The semiconductor device of claim 2, wherein
the first one or more gate structures and the second one or more gate structures are disposed based on a gate pitch along the first direction,
the first minimum via pitch is one of at least two times the metallization pitch or at least the gate pitch, and
the second minimum via pitch is one of at least two times the metallization pitch or at least the gate pitch.

4. The semiconductor device of claim 3, wherein
the first circuit cell further comprises third one or more via structures between the first metallization line region and a third metallization line region of a second metallization layer above the first metallization layer,
the second circuit cell further comprises fourth one or more via structures between the second metallization line region and a fourth metallization line region of the second metallization layer, and
the third one or more via structures are spaced apart from the fourth one or more via structures based on at least a third minimum via pitch that is greater than the metallization pitch.

5. The semiconductor device of claim 4, wherein
the third minimum via pitch is one of at least two times the metallization pitch or at least the gate pitch.

6. The semiconductor device of claim 4, wherein
the first circuit cell further comprises a third conductive line of the second metallization layer,
the second circuit cell further comprises a fourth conductive line of the second metallization layer,
the third conductive line and the fourth conductive line are aligned along the second direction, and
the third conductive line and the fourth conductive line are disposed based on a minimum end-to-end distance that is along the second direction and is greater than the metallization pitch.

7. The semiconductor device of claim 1, wherein
the first one or more drain/source conductive structures and the second one or more drain/source conductive structures are spaced apart based on a cut metal-on-diffusion (CMD) pattern, and
the CMD pattern has a third zig-zag pattern along the cell boundary.

8. The semiconductor device of claim 1, wherein
the first one or more gate structures and the second one or more gate structures are spaced apart based on a cut poly (CPO) pattern, and
the CPO pattern has a fourth zig-zag pattern along the cell boundary.

9. A method of generating a layout plan for a semiconductor device, comprising:
placing a first layout cell in the layout plan, the first layout cell indicative of a first circuit cell, including first one or more conductive line patterns indicative of first one or more conductive lines in a first metallization line region of a first metallization layer, and including first one or more via patterns indicative of first one or more via structures under the first metallization layer;
placing a second layout cell in the layout plan, the second layout cell indicative of a second circuit cell, abutting the first layout cell at a cell boundary therebetween, including second one or more conductive line patterns indicative of second one or more conductive lines in a second metallization line region of the first metallization layer, and including second one or more via patterns indicative of second one or more via structures under the first metallization layer; and
saving, to a memory of a processing device, the layout plan that includes the first layout cell and the second layout cell,
wherein
the first metallization line region and the second metallization line region are spaced apart by a shared space extending along the cell boundary,
based on the first one or more via patterns and the second one or more via patterns belonging to a first via layer between the first metallization layer and a drain/source conductive layer of the layout plan, the first one or more via patterns and the second one or more via patterns are within a first area having a first zig-zag pattern along the cell boundary, and
based on the first one or more via patterns and the second one or more via patterns belonging to a second via layer between the first metallization layer and a gate layer of the layout plan, the first one or more via patterns and the second one or more via patterns are within a second area having a second zig-zag pattern along the cell boundary.

10. The method of claim 9, wherein
the cell boundary extends along a first direction,
the first metallization line region and the second metallization line region are disposed based on a metallization pitch along a second direction different from the first direction,
based on the first one or more via patterns and the second one or more via patterns belonging to the first via layer between the first metallization layer and the drain/source conductive layer of the layout plan, the first one or more via patterns and the second one or more via patterns are disposed based on a first minimum via pitch that is greater than the metallization pitch, and
based on the first one or more via patterns and the second one or more via patterns belonging to the second via layer between the first metallization layer and the gate layer of the layout plan, the first one or more via patterns and the second one or more via patterns are disposed based on a second minimum via pitch that is greater than the metallization pitch.

11. The method of claim 10, wherein
one or more gate patterns in the gate layer of the layout plan are disposed based on a gate pitch along the first direction,
the first minimum via pitch is one of at least two times the metallization pitch or at least the gate pitch, and
the second minimum via pitch is one of at least two times the metallization pitch or at least the gate pitch.

12. The method of claim 10, wherein
the first layout cell further comprises third one or more via patterns belonging to a third via layer between the first metallization line region and a third metallization line region of a second metallization layer above the first metallization layer,
the second layout cell further comprises fourth one or more via patterns belonging to the third via layer, and
the third one or more via patterns are spaced apart from the fourth one or more via patterns based on at least a third minimum via pitch that is greater than the metallization pitch.

13. The method of claim 12, wherein
the third minimum via pitch is one of at least two times the metallization pitch or at least the gate pitch.

14. The method of claim 12, wherein
the first layout cell further comprises a third conductive line pattern of the second metallization layer,
the second layout cell further comprises a fourth conductive line pattern of the second metallization layer,
the third conductive line pattern and the fourth conductive line pattern are aligned along the second direction, and
the third conductive line pattern and the fourth conductive line pattern are disposed based on a minimum end-to-end distance that is along the second direction and is greater than the metallization pitch.

15. The method of claim 9, wherein
the first layout cell and the second layout cell include portions of a cut metal-on-diffusion (CMD) pattern for defining first one or more drain/source conductive structures of the first circuit cell and second one or more drain/source conductive structures of the second circuit cell, and
the CMD pattern has a third zig-zag pattern along the cell boundary.

16. The method of claim 9, wherein
the first layout cell and the second layout cell include portions of a cut poly (CPO) pattern for defining first one or more gate structures of the first circuit cell and second one or more gate structures of the second circuit cell, and
the CPO pattern has a fourth zig-zag pattern along the cell boundary.

17. A method of generating a layout plan for a semiconductor device, comprising:
obtaining a set of placement sites from a plurality of placement sites of the layout plan for a target layout cell indicative of a target circuit cell, each one of the plurality of placement sites of the layout plan having a width along a first direction corresponding to a gate pitch of the layout plan and a height along a second direction corresponding to a standard cell height of the layout plan, the plurality of placement sites
including a first row of placement sites including first placement sites of a first placement type and second placement sites of a second placement type arranged in an alternative manner along the first direction and usable for placing a standard layout cell of the standard cell height in a nominal form, and
including a second row of placement sites including third placement sites of a flipped first placement type and fourth placement sites of a flipped second placement type arranged in an alternative manner along the first direction and usable for placing the standard layout cell in a flipped form that corresponds to mirroring the nominal form about an axis along the first direction,
a shared space being defined along a boundary between the first row and the second row, the shared space being free of any layout patterns in a first metallization layer of the layout plan,
the first placement sites of the first row of placement sites abutting the fourth placement sites of the second row of placement sites,
the second placement sites of the first row of placement sites abutting the third placement sites of the second row of placement sites,
the first placement type indicating accommodating a via pattern under the first metallization layer of the layout plan disposed adjacent to a reversed second direction side of a corresponding placement site, and
the second placement type indicating prohibiting any via pattern under the first metallization layer of the layout plan disposed adjacent to the reversed second direction side of the corresponding placement site;
placing one of a plurality of candidate layout cells associated with the target circuit cell as the target layout cell at the set of placement sites based on a placement site type of an edge placement site of the set of placement sites in a reversed first direction; and
saving, to a memory of a processing device, the layout plan that includes the layout cell.

18. The method of claim 17, wherein
the plurality of candidate layout cells associated with the target circuit cell comprises a candidate layout cell including first one or more layout regions and second one or more layout regions arranged in an alternative manner along the first direction, each one of the first one or more layout regions and the second one or more layout regions corresponding to a respective placement site,
each one of the first one or more layout regions is based on accommodating via patterns under the first metallization layer of the layout plan placed adjacent to opposite sides of the candidate layout cell with respect to the second direction, and
each one of the second one or more layout regions is based on prohibiting any via patterns under the first metallization layer of the layout plan placed adjacent to opposite sides of the candidate layout cell with respect to the second direction.

19. The method of claim 17, wherein
the plurality of candidate layout cells associated with the target circuit cell comprises a candidate layout cell including first one or more layout regions and second one or more layout regions arranged in an alternative manner along the first direction, each one of the first one or more layout regions and the second one or more layout regions corresponding to a respective placement site,
each one of the first one or more layout regions is based on accommodating a first via pattern under the first metallization layer of the layout plan placed adjacent to a first side of the candidate layout cell and prohibiting any via patterns under the first metallization layer of the layout plan placed adjacent to a second side of the candidate layout cell,
each one of the second one or more layout regions is based on accommodating a second via pattern under the first metallization layer of the layout plan placed adjacent to the second side of the candidate layout cell and prohibiting any via patterns under the first metallization layer of the layout plan placed adjacent to the first side of the candidate layout cell, and
the first side of the candidate layout cell and the second side of the candidate layout cell are opposite sides with respect to the second direction.

20. The method of claim 17, wherein
the target layout cell has a cell height of the standard cell height, or the target layout cell has the cell height of two times the standard cell height.
